(19) United States
(12) Patent Application Publication
(10) Pub. No.: US 2015/0228325 A1
(43) Pub. Date: Aug. 13, 2015

(54) FBC MEMORY OR THYRISTOR MEMORY FOR REFRESHING UNUSED WORD LINE

(71) Applicant: PS4 Luxco S.a.r.l., Luxembourg (LU)

(72) Inventors: Shuichi Tsukada, Tokyo (JP); Yasuko Hattori, Tokyo (JP); Natsuki Sato, Tokyo (JP)

(21) Appl. No.: 14/424,949

(22) PCT Filed: Aug. 23, 2013
(86) PCT No.: PCT/JP2013/072553

§ 371 Date: Feb. 27, 2015

(30) Foreign Application Priority Data
Aug. 29, 2012 (JP) 2012-188523

(51) Int. Cl. G11C 11/406; G11C 11/4091; G11C 11/408

(52) U.S. Cl. CPC G11C 11/406; G11C 11/4085; G11C 11/4091

(57) ABSTRACT

The semiconductor device includes: a word line; a bit line: a power supply node; a plurality of memory elements including at least first and second regions that form a PN junction between the bit line, and the power supply node, and a third region that forms a PN junction with the second region; and a control circuit which, during a refresh operation, activates both a used word line that is accessed during reading and writing operations and an unused. word line that is not accessed during the reading and writing operations, and sets a potential of the second region of each of the used word line and the unused word line at a predetermined voltage.

### DESCRIPTION OF RELATED APPLICATIONS

The present invention claims the priority of Japanese Patent Application Publication No. 2012-188523 (filed on Aug. 29, 2012), the entire contents of which are incorporated into this specification by reference.

### TECHNICAL FIELD

The present invention relates to a semiconductor device, and more particularly to a thyristor memory or an FBC (Floating Body Cell) memory that stores a charge in a floating body, which is a semiconductor region in a floating state.

### BACKGROUND ART

A memory of a type that stores information by storing a charge in a floating body node, for example a thyristor memory or an FBC memory, has been proposed as an alternative memory to a DRAM, which is currently in mainstream use as a main memory. Non-Patent Document 1 describes a thyristor memory, and Patent Document 1 describes an FBC memory.

FIG. 18A is an equivalent circuit diagram showing a memory cell of the thyristor memory described in Non-Patent Document 1. An NMOS transistor M1 having an FB node as a substrate is provided, and a P-type semiconductor region is connected to an FN node of a drain of the NMOS transistor M1. As a result, a PNP bipolar transistor Q2 and a parasitic NPN bipolar transistor Q1 are formed, and thus a thyristor structure is obtained. An emitter of the PNP bipolar transistor Q2, a base of which is formed from an N-type region of the FN node, is connected to a bit line BL (an anode), a gate of the NMOS transistor M1 is connected to a word line WL, and a source of the NMOS transistor M1 is connected to a VSS (a cathode). The FB node is in a floating state when unselected, and a memory operation is performed by storing a charge in a gate capacitor between the gate of the NMOS transistor M1 and the FB node.

FIG. 18B is an equivalent circuit diagram showing a memory cell of the FBC memory described in Patent Document 1. An NMOS transistor M1 having an FB node as a substrate is provided, and a parasitic NPN bipolar transistor Q1 is formed. A drain of the NMOS transistor M1 is connected to a bit line BL (a drain), a gate of the NMOS transistor M1 is connected to a word line WL, and a source of the NMOS transistor M1 is connected to a VSS (a source). The FB node is floating when unselected, and a memory operation is performed by storing a charge in a gate capacitor between the gate of the NMOS transistor M1 and the FB node. Similarly to a DRAM, a thyristor memory and an FBC memory must both be refreshed periodically.

Patent Document 1: Japanese Patent Application Publication No. 2009-176331

Non-Patent Document 1: S. Slesazeck et al., “Vertical Capacitor-less Thyristor Cell for 30 nm Stand-alone DRAM”, 2009 Symposium on VLSI Technology Digest of Technical Papers P232-233

### DISCLOSURE OF THE INVENTION

Note that the disclosures of the respective prior art documents described above are incorporated herein by reference. Following analysis is given by the present invention. In both Patent Document 1 and Non-Patent Document 1, information is stored by storing a charge in the gate capacitor between the gate of the MOS transistor and the FB node. In a memory cell in which a charge is stored in a floating body, the MOS transistor functions as a trigger element of a thyristor or a bipolar transistor. However, use of a MOS transistor causes following problems.

As described in Non-Patent Document 1, a GIDL (Gate Induced Drain Leakage) current is present in the MOS transistor, and a large negative voltage needs to be applied particularly to the gate that controls the floating body when unselected, leading to an increase in the GIDL current. As a result of this leakage current, a refresh characteristic during a data retention period deteriorates. GIDL is generally considered to be the principle cause of a cell leakage current.

Further, ion implantation conditions must be determined. to ensure that characteristics such as a Vt value of the MOS transistor are appropriate, and it is therefore impossible to adjust the leakage current of each PN junction portion to a profile at which junction leakage is minimized. Moreover, as described in Non-Patent Document 1, to prevent an area increase when a MOS transistor is used in a memory cell, a thyristor or a bipolar transistor may be formed vertically in a columnar or wall-shaped region provided. on a semiconductor substrate, and a gate (a word line) may be provided on a side wail thereof. However, it is difficult to process the word line, and. therefore miniaturization is also difficult.

In view of these points, a MOS transistor is preferably not provided in either of the memory cells having floating bodies disclosed in Patent Document 1 and Non-Patent Document 1. When the DIGS transistor serving as the trigger element is not provided, however, it may be difficult to control conductive and non-conductive states of the memory cell reliably.

Furthermore, in a memory cell connected to an unused word line that is not used during reading and writing operations, such as a replaced word line replaced by redundancy, an unused redundant word line, or a dummy word. line at a cell region end, a voltage of the floating body is unstable, and this instability may cause a reading defect in another memory cell. Note that this problem will be described in detail below.

A first aspect of the present invention provides a semiconductor device including: a word line; a bit line: a power supply node; a plurality of memory elements including at least first and second regions that form a PN junction between the bit line and the power supply node, and a third region that forms a PN junction with the second region; and a control circuit which, during a refresh operation, activates both a used word line that is accessed during reading and writing operations and an unused word line that is not accessed during the reading and writing operations, and sets a potential of the second region of each of the used word line and the unused word line at a predetermined voltage.

According to the present invention, during the refresh operation, the control circuit activates the unused word line in addition to the used word line that is activated during writing and reading operations, and sets a voltage of a floating body of The memory element of the unused word line at a predetermined level. As a result, a problem whereby a memory cell in which the voltage of the floating body is unstable may cause a reading defect in another memory cell can be avoided.

### BRIEF DESCRIPTION OF THE DRAWINGS

FIG. 1 is a circuit diagram showing a sense amplifier according to a first embodiment;

FIG. 2 is an overall block diagram showing a semiconductor device according to the first embodiment;

FIG. 3A is a circuit diagram showing a memory cell (a thyristor memory) according to the first embodiment, and FIG. 3B shows a corresponding simplified circuit diagram symbol;

FIG. 4 is a circuit layout diagram showing a periphery of a memory cell region according to the first embodiment;

FIG. 5 is a plan view of the memory cell region according to the first embodiment;

FIG. 6 is an A-A sectional view of the memory cell region according to the first embodiment;

FIG. 7 is a view showing memory cell write waveforms according to the first embodiment;

FIG. 8 is a view showing memory cell read waveforms according to the first embodiment;

FIG. 9 is a view showing examples of circuit configurations of a refresh control circuit and a redundancy determination circuit according to the first embodiment;

FIG. 10 is a view showing examples of waveforms generated during a refresh operation according to a second embodiment;

FIG. 11 is a view showing examples of circuit configurations of a refresh control circuit and a redundancy determination circuit according to a third embodiment;

FIG. 12 is a view showing examples of refresh control waveforms generated in relation to an unused word line according to the third embodiment;

FIG. 13 is a view showing examples of circuit configurations of a refresh control circuit and a redundancy determination circuit according to a fourth embodiment;

FIG. 14 is a view showing examples of waveforms generated when an extended address flag signal EPX signal is activated during refreshing according to the fourth embodiment;

FIG. 15 is a circuit layout diagram showing a periphery of a memory cell region according to a fifth embodiment;

FIG. 16 is a circuit diagram showing a memory cell (an FBC memory);

FIG. 17 is an A-A sectional view of the memory cell region shown in FIG. 16; and

FIG. 18A is a circuit, diagram of a conventional thyristor memory cell, and FIG. 18B is a circuit diagram of a conventional FBC memory cell.

### BEST MODE FOR CARRYING OUT THE INVENTION

Before embarking on a detailed description of respective embodiments of the present invention, a brief description of the embodiments of the present invention will be provided. Note that drawings cited in this brief description and reference symbols applied to the description from the drawings are merely examples used to aid understanding, and the present invention is not limited to the illustrations in the drawings.

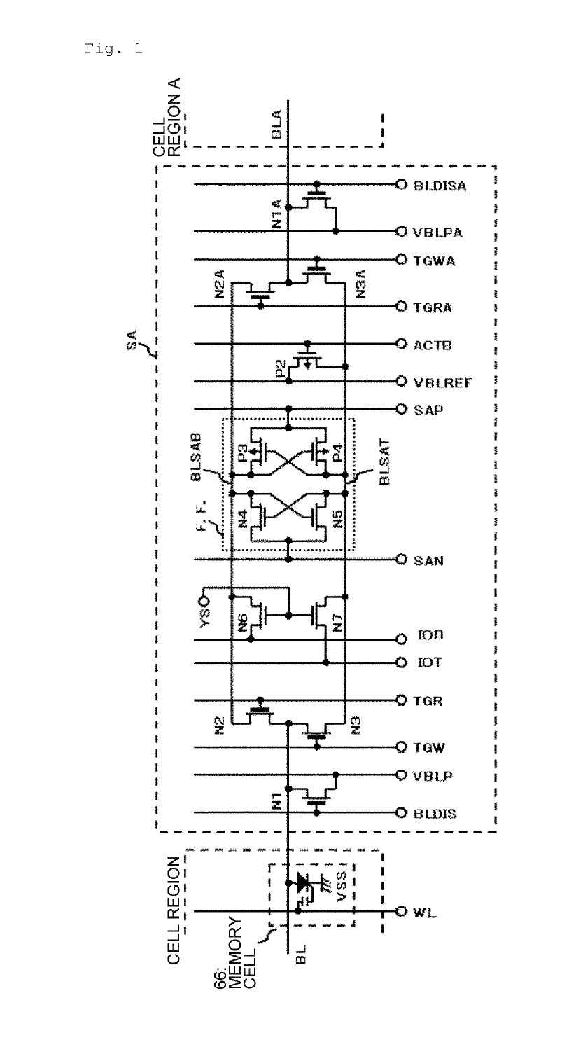

As shown in FIGS. 1, 2, 3, 4, 5, 6, and 9, for example, a semiconductor device (30) according to an embodiment includes a bit line (BL), a word line (WL), a plurality of memory elements (66) including at least first and second regions (2 and 3) that form a PN junction between the bit line and a power supply node, and a third region (8) that forms a PN junction with the second region (3), and a control circuit (40, 42, 43, 71) that additionally activates an unused word line periodically during a refresh operation, and applies currents between the respectively corresponding second regions and first regions in order to set a potential of each second region at a predetermined voltage.

According to the embodiment described above, during the refresh operation, the unused word line is activated in addition to a used word line that is activated during writing and reading operations, and a voltage of a floating body of the memory element. of the unused word line is set at a predetermined level. In so doing, the existence of a memory cell in which. the voltage of the floating body is unstable can be eliminated, and as a result, reading defects in other memory cells can be prevented.

Following aspects are also possible.

### Embodiment 1

The semiconductor device is as described above in the first aspect.

### Embodiment 2

The unused word Line is preferably a replaced. word line replaced in a redundancy replacement process, and/or an unused redundant word line not used in the replacement process, and/or a dummy word line.

### Embodiment 3

A refresh address counter that counts not only an address value of the used word line but. also an address value of the unused word line is preferably further included.

### Embodiment 4

A redundancy determination circuit that performs a logical operation on a redundancy determination output and a refresh address serving as an output of the refresh address counter in order to determine whether the refresh address is an address of the used word line or an address of the unused word line, and outputs the determination output, is preferably further included.

### Embodiment 5

The plurality of memory elements are preferably defined. as memory elements that hold first and second data respectively when the respective second regions thereof are at a first level, and a second level that is higher than the first level, and when, based on the determination output, the refresh address is the address of the unused word line, a potential of the second. region of the memory element connected to the unused word line is preferably set at the first level.

### Embodiment 6

The plurality of memory elements are preferably defined as memory elements that hold first. and second data respectively when the respective second regions thereof are at a first level and a second level that is higher than the first level, and when, based on the determination output, the refresh address is the address of the unused word line, a potential of the second region of the memory element connected to the unused word line is preferably set at a lower potential than the first level.

### Embodiment 7

When, based on the determination output, the refresh address is the address of the unused word line, an operation of a sense amplifier is preferably stopped, and the word line is preferably operated.

### Embodiment 8

When, based on the determination output, the refresh address is the address of the unused word line, a voltage of the word line is preferably set at a third word line voltage, which is higher than a second word line voltage that is applied to the word line when data are written to the memory element, from a first word line voltage, whereupon the voltage or the word line is set at the second. word line voltage and then. at the first word line voltage.

### Embodiment 9

When, based on the determination output, the refresh address is the address of the unused word line, a voltage of the word line is preferably set at a third word line voltage, which is higher than a second word line voltage that is applied to the word line when data are written to the memory element, from a first word line voltage, and then set. at the first. word line voltage without being held at the second word. line voltage.

### Embodiment 10

A function for determining whether the refresh address is the address of the used word line or the address of the unused word line by performing a logical operation on the redundancy determination output and the refresh address, outputting the determination output, and counting the address of the unused word line consecutively during an address count by the refresh address counter, is preferably further included.

### Embodiment 11

In response to a single refresh. instruction signal, an operation for performing a plurality of address counts and an operation for setting the potentials of the second regions of the memory elements connected to a plurality of the unused word lines at the predetermined level are preferably respectively performed continuously.

### Embodiment 12

The number of address counts performed in response to a single refresh instruction signal is preferably set at a factor of the number of addresses of the unused word lines.

### Embodiment 13

An operation is preferably performed to connect all or a plurality of the dummy word lines in The semiconductor device and drive the dummy word lines such that the potentials of the respective second regions of the memory elements connected to all or the plurality of the driven dummy word lines are set simultaneously at the predetermined level.

### Embodiment 14

The memory elements connected to one or a plurality of dummy word lines located at ends of respective memory regions are preferably electrically disconnected from the bit line.

### Embodiment 15

The memory elements connected to the dummy word lines are preferably disconnected from the bit line by not forming a bit line contact in the memory elements.

### Embodiment 16

The memory element is preferably a thyristor further having a fourth region that forms a PN junction with the third region and is removed from the second region, and the bit line is preferably electrically connected to the fourth region.

### Embodiment 17

The memory element is preferably a bipolar transistor, and the bit. line is preferably electrically connected to the third region.

Note that in this specification, excluding cases where different. interpretations are particularly evident from the context, a “cell High” denotes a memory cell holding high level data, and a “cell Low” denotes a memory cell holding low level data.

Further, in this specification, a “cell High. cell write waveform” is a waveform generated when high level data are written to a memory cell, and a “cell. Low cell, write waveform” is a waveform generated when to level data are written to a memory cell.

In this specification, a “cell High cell read waveform” is a waveform generated when data are read from a memory cell storing high level data, and a “cell Low cell read waveform” is a waveform generated when data are read. from a memory cell storing low level data.

In this specification, “BL “H”” denotes the bit line FL used. when high level data are written to a memory cell or high. level data are read from a memory cell.

In this specification, “BL “L”” denotes the bit line FL used when low level data are written to a memory cell, or low level data are read from a memory cell.

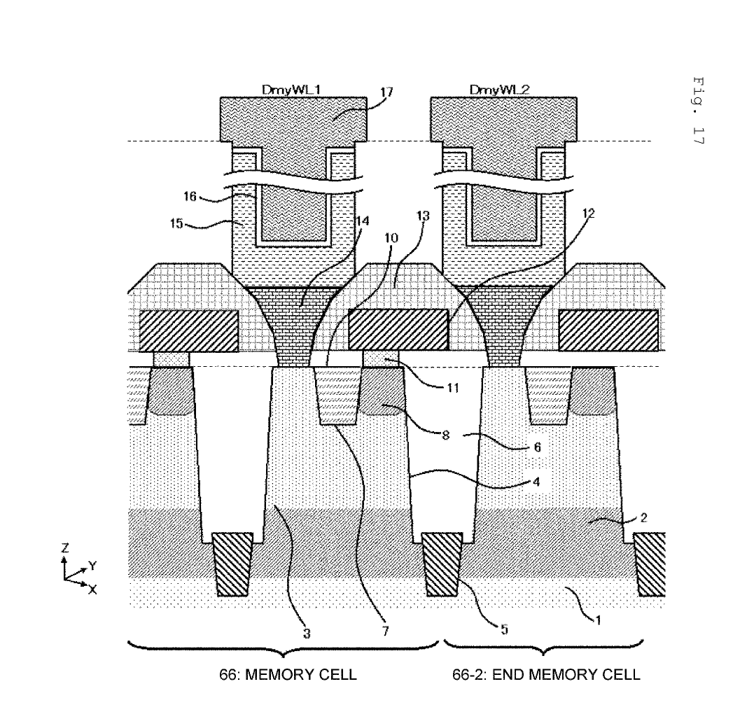

In this specification, “FB “H”” denotes a floating body (an FB node) in a case where a memory cell holds high level data, and “FB “L”” denotes an FB node in a case where a memory cell holds low level data. FIG. 3A shows an example of an FB node in a case where the memory cell is a thyristor memory cell, and FIG. 16 shows an example of an FS node in a case where the memory cell is an FBC memory cell.

In the description of the specification and the claims, a specific voltage may be described as being equal to another voltage. It goes without saying that in such cases, the two voltages are to be interpreted as being substantially equal.

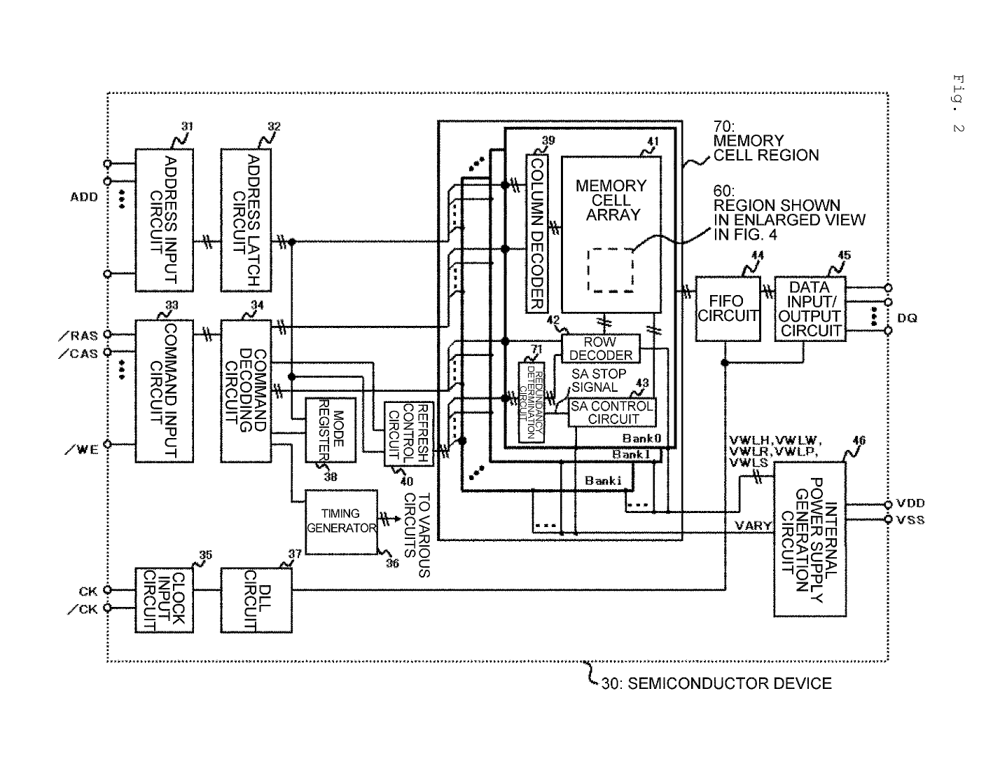

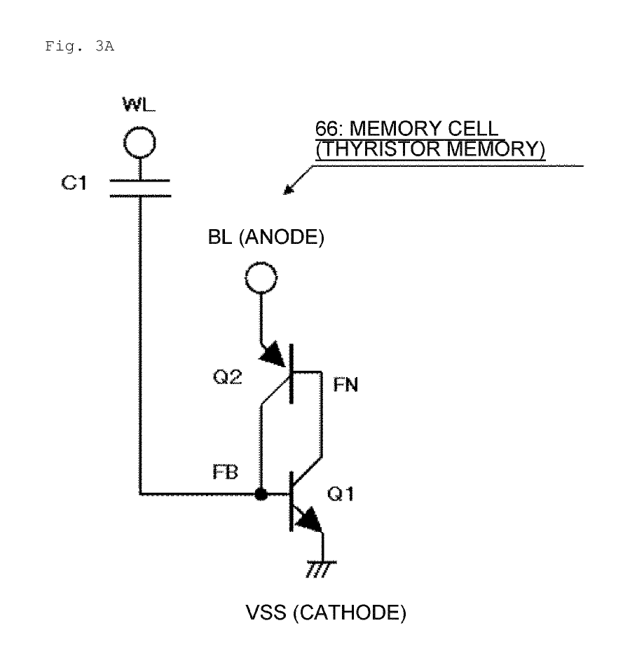

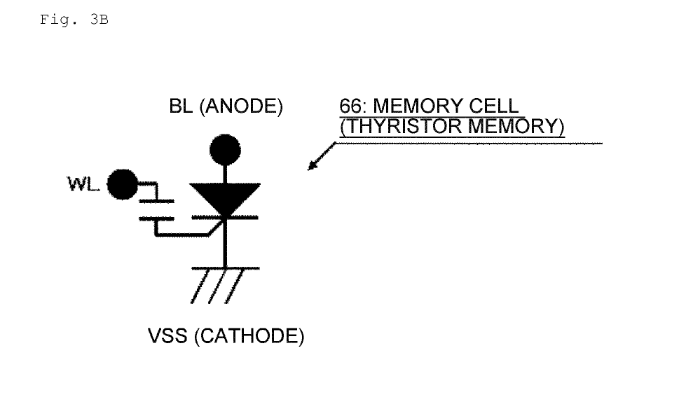

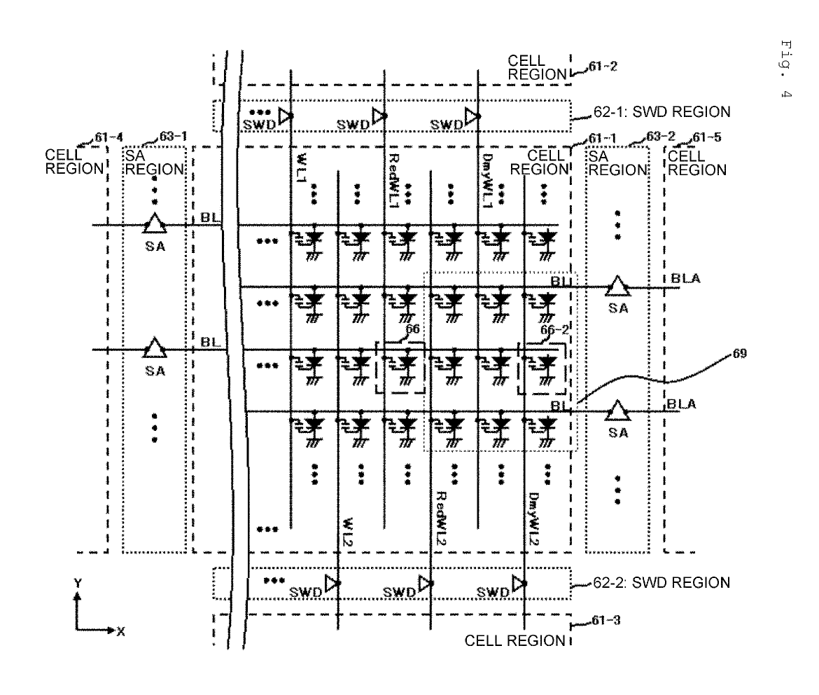

In this specification, a “normal word line” denotes a word line that is activated in .response to an externally specified row address in a state prior to a. redundancy replacement. process (word lines WL1 and WL2 in FIG. 4 correspond to normal word lines)

In this specification, an “unused word line” denotes a replaced defective normal word line that is replaced in a redundancy replacement process performed during a wafer scan or the like following manufacture, or an unused redundant word line or dummy word line that is not used during the replacement process An unused word line is not activated in response to an externally specified row address. Further, data are not written to or read from a memory cell connected to an unused word line via a data input/output circuit. of the semiconductor device. A “used word line”, meanwhile, is a word line of a memory cell in which reading and writing are performed, and which is activated in response to an externally specified row address. In other words, a “used word line” denotes a word line among the normal word lines that has not been replaced by redundancy, or a word line among redundant word lines that has been replaced and is in use.

Specific embodiments will be described in further detail below with reference to the drawings.

### First Embodiment

A first embodiment will now be described in detail using the drawings.

FIG. 2 is an overall block diagram showing a semiconductor device according to the first embodiment. The semiconductor device according to the first embodiment is a semiconductor device 30 that has an interior memory cell region 70 and is capable of reading and writing data from and to a memory cell, array 41 included in respective banks of the memory cell region 70 through a data input/output terminal DQ on the basis of a command signal (/RAS, /CAS, /WE, and so on) and an address signal ADD applied from the outside in synchronization with a clock

An address input circuit 31 receives an address input from an address input terminal ADD. An address latch circuit 32 latches the address signal input into the address input circuit 31 in synchronization with the clock. A command. input. circuit 33 receives a command. signal such as /RAS, /CAS, or /WE input from the outside. Note that “/” added to the front of a signal name indicates an active low signal. A command decoding circuit 34 decodes the command signal input into the command input circuit 33 and controls operations of respective parts of the semiconductor device 30. A timing generator 36 generates operation timing signals of various circuits provided in the semiconductor device 30 on the basis of decoding results from the command decoding circuit. 34. A clock input circuit 35 receives clock signals CK, /CK input from the outside. A DLL circuit 37 generates a clock signal synchronized to an externally applied clock so that data are input and output at high speed in synchronization with the outside. A mode register 38 is a register that can be set externally by a command, and an internal operation is controlled by a value set in the mode register 38.

As noted above, the cell memory region 70 includes a plurality of banks Bank0 to Banki (where i is an integer of 1 or more; likewise hereafter). Further, each bank includes the memory cell array 41, a column decoder 39, a row decoder 42, an SA control circuit 43, and a redundancy determination circuit 71.

The memory cell array 41 is wired in a direction in which a plurality of bit lines (not shown) selected by the column decoder 39 and a plurality of word. lines (not shown) selected, by the row decoder 42 intersect, and a plurality of memory cells (not shown) are arranged in matrix form in accordance with these intersections An internal configuration of the memory cell array 41 will be described in detail below.

The column decoder 39 decodes a column address in the address signal, and selects a bit line of an accessed. memory cell from the plurality of bit lines (not shown in FIG. 2) of the memory cell array. A refresh control circuit 40 specifies a row address corresponding to a used word line and an unused word line to be refreshed. The row decoder 42 decodes the row address, and selects a word line of the memory cell array 41. The SA control circuit 43 controls an operation of a sense amplifier (not shown) provided in the interior of the memory cell array 41. The redundancy determination circuit 71 determines whether or not the row address is using a redundant word line (not shown in FIG. 2), and outputs an address for controlling the row decoder 42. Further, during a refresh operation, the redundancy determination circuit 71 generates an SA stop signal on the basis of a redundancy determination result and so on.

When a read command is executed, a FIFO circuit 44 converts a plurality of bits of data read in parallel, from the memory cell array 41 into serial data, and outputs the serial data to the data input/output circuit 45. Further, when a write command is executed, the FIFO circuit 44 converts data input in series from the DQ terminal via the data input/output circuit 45 into parallel data, and transmits the parallel data to the memory cell, array 41 as write data. The data input/output circuit 45 inputs and outputs data between the FIFO circuit 44 and the DQ terminal serving as the data input/output terminal. Further, a clock is supplied to the FIFO circuit 44 and the data input/output circuit 45 from the DLL circuit 37, and control is performed so that data are input and output into and from an external device at high speed in synchronization with the clock. An internal power supply generation circuit 46 generates power supplies required for internal operations using power supplied from external power supply terminals VDD, VSS. Main power supplies generated by the internal power supply generation circuit 46 will now be described. VARY is a power supply supplied to the SA control circuit 43 in order to drive, the bit lines to a high level. A word line overshoot voltage VWLH a word line write voltage VWLW a word line read voltage VWLR, a word line pre-charge voltage VWLP, and a word line standby voltage VWLS are respectively voltages that serve as power supplies supplied. to the row decoder 42 in order to drive the word lines.

FIG. 4 is a circuit layout diagram showing a periphery of the memory cell region according to the first embodiment. FIG. 4 shows a circuit layout inside a region 60 indicated by dotted lines in the memory cell array 41 of FIG. 2. A large number of cell regions 61 shown in FIG. 4 are arranged in matrix form inside the memory cell array 41 of FIG. 2, and FIG. 4 shows a circuit layout of one cell region 61-1 of the large number of cell regions 61 arranged in matrix form and a periphery at the cell region 61-1.

SWD regions 62-1 and 62-2, which are regions in which sub-word drivers SWD are respectively disposed, are provided above and below the cell region 61-1. (Sub-)word lines are wired alternately to the cell region 61-1 from the sub-word drivers SWD provided in the SWD regions 62-1 and 62-2. In FIG. 4, the normal word lines WL1 and WL2 are wired.

Dummy word lines and redundant word lines are wired to The cell region 61-1 in addition to the normal word lines. A processed shape of a repeatedly disposed memory cell may deform at an end of the cell region such that an electric characteristic of the memory cell differs from that of inner side memory cells. Therefore, the memory cells disposed at the ends of the cell region are not used as storage elements. Word lines connected to the memory cells disposed at the ends of the cell region 61 are set as dummy word lines. In FIG. 4, dummy word lines DmyWL1 and DmyWL2 are wired. Further, the dummy word line DmyWL2 that is wired furthest toward the end of the cell region is not connected to the bit line BL. The dummy word line DmyWL2 uses a plurality of end memory cells 66-2 that do not connect an anode to a bit line. Note that the dummy word lines can also be driven by the sub-word drivers SWD. Furthermore, in FIG. 4, redundant word lines RedWL1 and RedWL2 are wired as redundant word lines.

Further, the normal word line WL1, which is driven by the sub-word driver SWD provided in the SWD region 62-1, is also wired. to an adjacent cell region 61-2 to the cell region 61-1 via the SWD region 62-1. The normal word line WL2, which is driven by the sub-word driver SWD provided in the SWD region 62-2, is also wired to a cell region 61-3. This applies likewise to the dummy word lines DmyWL1 and DmyWL2 and the redundant word lines RedWL1 and RedWL2.

SA regions 63-1, 63-2, which are regions in which sense amplifiers SA are respectively disposed, are provided to the left. and right of the cell region 61-1. The bit lines In are alternately wired to the cell region 61-1 from the sense amplifiers SA provided in the SA regions 63-1, 63-2. Further, separate bit lines BL are wired to an adjacent cell region 61-4 to the cell region 61-1 from she sense amplifier SA provided in the SA region 63-1 via the SA region 63-1. Similarly, separate bit lines BLA are wired to a cell region 61-5 from the sense amplifier SA provided in the SA region 63-2. A plurality of memory cells 66 are arranged in matrix form. in an internal region of the cell region 61-1, excluding the dummy word line DmyWL2 furthest toward the end of the cell region, in accordance with intersections between the respective bit lines BL and she respective word lines WL (including a part of the dummy word lines and the redundant word lines). Furthermore, the plurality of end memory cells 66-2 are disposed in accordance with intersections between the respective bit lines BL and the dummy word line DmyWL2.

Next, the memory cells 66 included in the semiconductor device 30 according to this first embodiment will be described. FIG. 3A shows an internal, circuit of one of the memory cells 66 shown in FIG. 4. In FIG. 3A, a thyristor is provided between the bit line BL and a power supply node VSS such that an anode thereof is connected to the bit line BL and a cathode thereof is connected to she power supply node VSS. The thyristor includes an NPN transistor Q1 having an emitter connected to the cathode, a base connected to a floating body FB, and a collector connected to a region FN, and a PNP transistor Q2 having an emitter connected to the anode, a base connected. to the region FN, and a collector to the floating body FB. In addition, a capacitor C1 is provided between the floating body FB and the word line WL. FIG. 3B shows a simplified circuit diagram symbol of the memory cell 66 used in FIGS. 1, 4, and so on. More specifically, the memory cell 66 in FIG. 4 includes a single thyristor and the single capacitor C1, but does not include a MOS transistor.

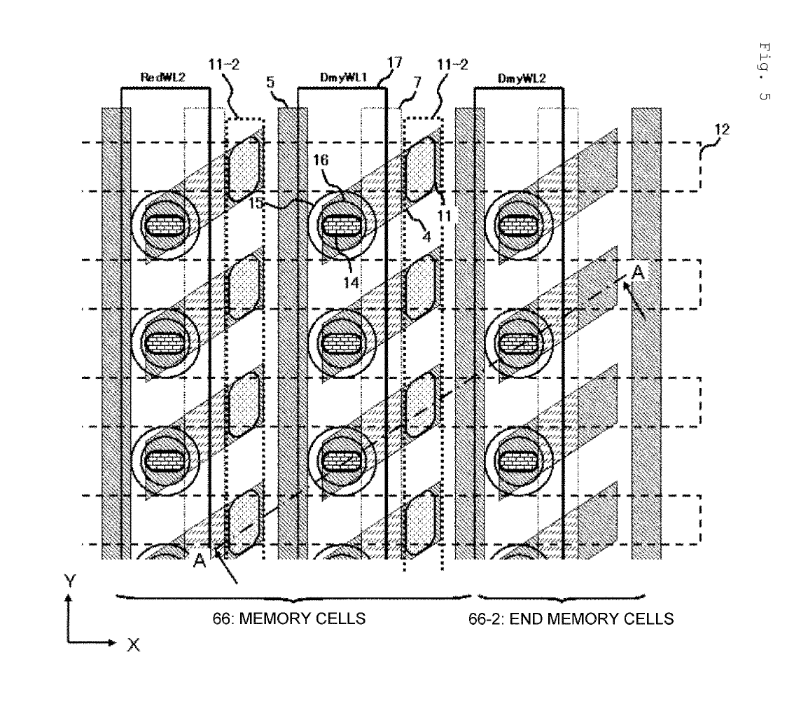

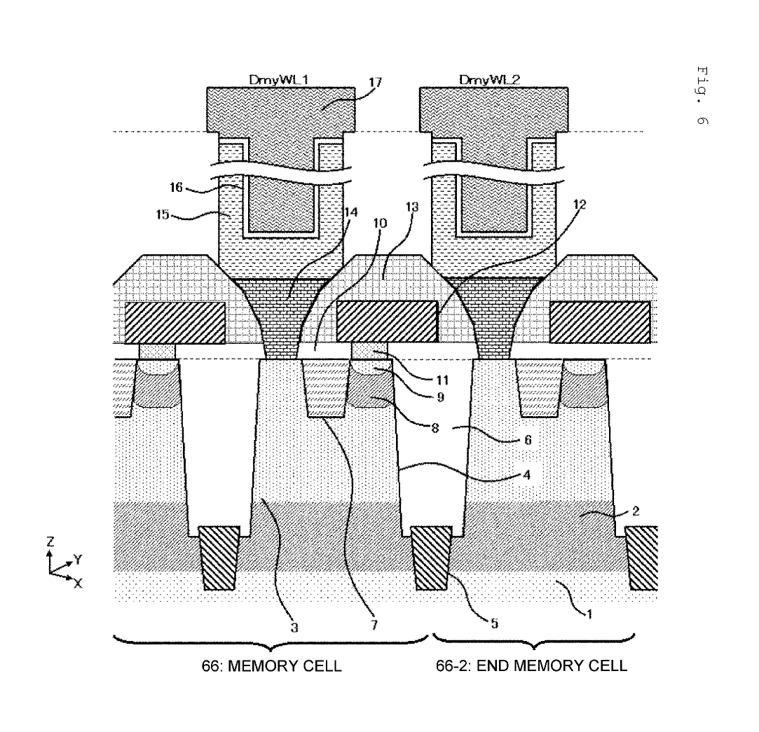

FIG. 5 is a plan view showing an example of the memory cell region according to the first embodiment. A plane shown in FIG. 5 is a planar region within dotted lines indicated by a reference numeral 69 in FIG. 4. Further, FIG. 6 is a sectional view showing an A-A cross-section of FIG. 5 from a direction of an arrow. In FIG. 6, an N-type cathode 2 and a diffusion layer 4 of a P-body 3 are stacked in that order onto a main surface of a P-type semiconductor substrate 1. An STI (shallow trench isolation) 6 is provided in a wedge shape in a surface of the diffusion layer 4, and extends into the N-type cathode 2. Respective memory cells are defined by the STI 6. Further, an embedded metal 5 is provided in a bottom surface of each STI 6 so as to contact the P-type semiconductor substrate 1 and the N-type cathode 2. The N-type cathodes 2 are electrically connected via the embedded metal 5, thereby serving as a shared power supply node of the memory cells. A recess 7 is provided in a wedge shape in the surface of the diffusion layer 4 in the center of a surface of the P-body 3 of each of the memory cells divided by the STIs 6. An N-type diffusion layer 8 and a P-type anode 9 serving as a P-type diffusion layer are stacked in that order onto the surface, of the P-body 3 of each memory cell on one of the two sides divided by the recess 7.

An interlayer film 10 is provided on the surface of the diffusion layer 4 including the P-type anode 9 so as to cover the entire surface. In the memory cell 66, a bit line contact 11 is provided on the interlayer film 10 on the surface of the P-type anode 9, and the P-type anode 9 is connected to a bit line 12 provided on an upper layer of the interlayer film 10 via the bit line contact In the end memory cells 66-2, the bit line contact 11 is not formed, and the interlayer film 10 is provided between the P-type anode 9 and the bit line 12. Side faces and an upper surface of the bit line 12 are covered by a side wall 13 formed from a nitride film. Further, a capacitance contact 14 is provided on the other side of the surface of the P-body 3, which is divided. by the recess 7, to the N-type diffusion layer 8 and the P-type anode 9 so as to penetrate the interlayer film 10, and is connected to a lower electrode 15 of a capacitor provided on a layer above the bit line 12. Furthermore, a word line 17 is provided as an uppermost wiring layer of the memory cell structure on an upper layer of the lower electrode 15 via a capacitance film 16.

In the memory cell 66, the P-type anode 9 of the thyristor, which is constituted by the P-type anode 9, the N-type diffusion layer 8, the P-body 3, and the N-type cathode 2, is connected to the bit line 12 via the bit line contact 11, and the N-type cathode 2 of the thyristor serves as a power supply node. Further, the N-type cathode 2 and/or the embedded metal 5 are/is connected to the external power supply terminal VSS, not shown in the drawings. Moreover, the P-body 3 of the thyristor is connected to the word line 17 via the capacitance contact 14 and via a capacitor constituted by the (lower) electrode 15, the capacitance film 16, and the word line 17. Furthermore, by providing the recess 7, the P-type anode 9 and the N-type diffusion layer 8 are formed in a region that is separated from the P-body 3 connected to the capacitance contact 14 by the recess 7.

As shown in FIGS. 5 and 6, MOS transistors, including parasitic transistors, are not used in the memory cells. Therefore, problems caused when a MOS transistor is used in a memory cell, such as a GIDL current, do not occur. Furthermore, although the capacitor is electrically connected to the thyristor serving as the memory element via the capacitance contact 14, the capacitor and she thyristor serving as the memory element are provided independently. Hence, even when an impurity concentration or the like in each semiconductor region of the memory element is optimized, capacitor characteristics are not affected thereby. Moreover, a capacitor having a sufficient capacitance can be provided as required without affecting characteristics of the memory element.

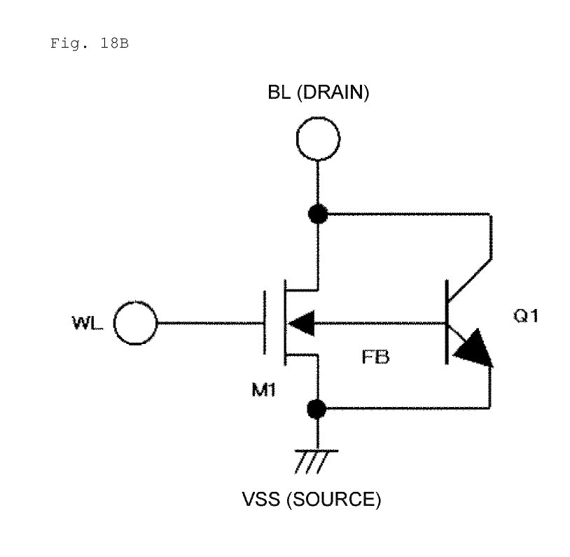

As described in Non-Patent Document 1, in the case of the conventional thyristor memory shown in FIG. 18A, in which the parasitic capacitance of the MOS transistor is used as the cell capacitance, a cell, capacitance value, between the body FB node (a back bias of the NMOS transistor) and the gate is extremely small at approximately 10 aF (attofarad: 1E-18) to 50 aF in a 30 nm process or less. If process miniaturization advances in the future, a surface area between the body FB node and the gate will decrease further, leading to a further reduction in the cell capacitance.

As a result, she refresh characteristic will deteriorate as soon as a slight cell leakage current occurs. Incidentally, the cell capacitance of a DRAM is approximately 25 fF (femtofarad: 1E-15), which is larger than the parasitic capacitance or an NMOS transistor by approximately 3 digits.

In the device structure example of FIG. 6, a concave capacitor structure (in which the electrode 15 is in the shape of a crown and capacitance is provided therein) is shown, but the capacitor can be formed by an identical process to that used to form a capacitor of a DRAM. Various structures exist as capacitor structures for a DRAM, and the present invention may be applied. to any structure. A typical DRAM requires a capacitance of approximately 20 fF or more in accordance with a product of the cell leakage current value and the required refresh characteristic, and in recent years it is becoming more difficult to secure this cell, capacitance while achieving miniaturization. With the semiconductor device of the present disclosure, however, the cell leakage current value can be improved significantly as described above, and therefore, when the refresh characteristic has an identical value to that of a DRAM, the cell capacitance can be reduced. When the cell leakage current can be reduced by two digits or more from that of a DRAM, a cell capacitance of approximately 0.32 fF, as described above, can be allowed.

Furthermore, the capacitance value of the capacitor can be reduced in principle below that of a DRAM. More specifically, when cell data are read, the word line WL and the bit line BL are selected, whereby the thyristor serving as the memory element operates as an active element that drives the bit line. Therefore, the capacitance can be reduced in principle in comparison with a DRAM that simply reads the capacitance of the memory cell via a switch. Moreover, the memory element requires only three PN junctions, and in contrast to a MOS transistor can be caused. to function as an active element without the use of a semiconductor substrate surface. Therefore, by providing the memory element vertically with respect to the semiconductor substrate, as shown in FIG. 6, a cell area can be reduced easily.

Operation Principle of Thyristor Memory Cell

Next, an outline of an operation principle of a thyristor memory cell will be described. with. reference to the circuit diagram in FIG. 3A. When the voltage of the FB one is increased from a low voltage via the capacitance of the cell capacitor such that the voltage between the FB node (a P-type region) and the cathode VSS (an N-type region) reaches a voltage close to a built-in potential voltage VBI of the PN junction, a forward direction current of a diode starts to flow from the FB node to the cathode VSS. This current is equivalent to a base-emitter current of the NPN bipolar transistor Q1.

When the voltage of the FB node is increased via the capacitance of the cell capacitor to a voltage close to the built-in potential voltage VBI while the voltage of the bit line BL (the anode) is sufficiently high, the NPN bipolar transistor Q1 switches ON weakly such that an FN node decreases gradually to a low level. Accordingly, the PNP bipolar transistor Q2 turns ON, thereby raising the voltage of the FB node even higher. As a result, the NPN bipolar transistor Q1 switches ON more strongly such that the anode EL and the cathode VSS of the thyristor memory cell enter a conductive state.

Once the thyristor memory cell enters the conductive state, as long as a sufficiently high voltage is applied to the hit line BL (the anode), the conductive state is maintained even when a coupling voltage is applied to the FB node via the capacitance of the cell capacitor.

The thyristor memory cell is switched to a non-conductive state by reducing a potential difference between the anode BL and the cathode VSS to a small potential difference equal to or smaller than the built-in potential voltage VBI. When the bit line BL is set at or below the built-in potential voltage VBI, the FB node decreases to or below the built-in potential voltage VBI due to the leakage current of the PN junction. Accordingly, the NPN bipolar transistor Q1 turns OFF, and as a result, the anode BL and the cathode VSS of the thyristor memory cell enter the non-conductive state.

When the bit line BL (the anode) is at a sufficiently low voltage no higher than the built-in potential voltage VBI, the NPN bipolar transistor Q1 and the PNP bipolar transistor Q2 remain switched OFF even after the voltage of the FB node is increased, and therefore the anode BL and the cathode VSS of the thyristor memory cell do not remain conductive at all times.

FIG. 1 is a circuit diagram of the sense amplifier SA according to the first embodiment. The bit line FL is connected to the sense amplifier SA from a cell region, and the bit line BLA is connected to The sense amplifier SA from an adjacent cell region A. One of a drain and a source of an N-type transistor N1 is connected to the bit line BL, and the other is connected to a bit. line drive power supply signal VBLP. Further, a gate of the N-type transistor N1 is connected to a bit line drive control signal BLDIS. The bit line drive power supply signal VBLP is a power supply signal output from the SA control circuit 43. Furthermore, an N-type transistor N1A is connected to the bit line BLA in a similar manner to the N-type transistor N1. The N-type transistors N1, N1A fix respective voltages of the bit Lines BL and BLA at the power supply VARY or the power supply VSS, irrespective of data held by the sense amplifier SA.

One of a source and a drain. of an N-type transistor N2 is connected to the bit line BL, and the other is connected to an inverting sense amplifier bit line BLSAB. A control signal TGR is connected to a gate of the N-type transistor N2. The control signal TGR is activated to the high level during an operation to read data on the bit line EL. During the reading operation, the bit line BL is connected to the inverting sense amplifier bit line BLSAB via the N-type transistor N2. An N-type transistor N2A is provided similarly between the bit line BLA and the inverting sense amplifier bit line BLSAB, and a control signal TGRA is connected to a gate of the N-type transistor N2A.

Further, one of a source and a drain of an N-type transistor N3 is connected to the bit line FL, and a non-inverting sense amplifier bit line BLSAT is connected to the other. A control signal TGW is connected to a gate of the N-type transistor N3. The control signal TGW is activated to the high level when the bit line BL is driven on the basis of the data in the sense amplifier SA during a write operation. During the write operation, the bit line BL is connected to the non-inverting sense amplifier bit line BLSAT via the N-type transistor N3. An N-type transistor N3A is provided similarly between the bit line BLA and the non-inverting sense amplifier bit line BLSAT, and a control signal TGWA is connected to a gate of the N-type transistor N3A.

A flip flop F.F. is provided between the inverting sense amplifier bit line BLSAB and the non-inverting sense amplifier bit line BLSAT to amplify a potential difference between the inverting sense amplifier bit line BLSAB and the non-inverting sense amplifier bit line BLSAT. The flip flop F.F. includes P-type transistors P3, P4 and N-type transistors N4, N5. In addition, respective power supplies SAP, SAN of the P-type transistors and the N-type transistors are connected to the flip flop F.F. The power supplies SAP and SAN are activated only when an operation of the flip flop F.F. is required. When activated, the power supplies SAP and SAN are set at identical potentials to the power supplies VARY and VSS, respectively. A maximum amplitude of the bit line BL is determined from voltages of the power supplies SAP and SAN and a voltage of the power supply VARY. When inactivated, the power supplies SAP and SAN are set at identical potentials to the power supplies VSS and VARY, respectively.

An N-type transistor N6 serves as a switch that connects the inverting sense amplifier bit line BLSAB to an inverting IO line IOB, and an N-type transistor N7 serves as a switch that connects the non-inverting sense amplifier bit line BLSAT to a non-inverting IO line IOT. Conduction and non-conduction of the N-type transistors N6 and N7 are controlled by a column selection signal YS. When data are written from the outside of the memory cell array and data in the memory cell array are read to the outside, the inverting sense amplifier bit line BLSAB of the sense amplifier SA is connected to the inverting IO line ION and the non-inverting sense amplifier bit. line BLSAT is connected to the non-inverting IO line IOT via the N-type transistors N6 and N7, whereupon the read and write data are input and output.

A P-type transistor P2 is connected between the non-inverting sense amplifier bit line BLSAT and a signal line on which a bit line reference voltage VBLREF is supplied. A control signal ACTB is connected to a gate of the P-type transistor P2. The control signal ACTB is activated to the low level during a read operation.

Note that thick-film transistors having higher withstand voltages than the peripheral transistors are used as the N-type transistors N1, N2, N3, N1A, N2A, N3A. NMOS and PMOS transistors can be used favorably as the N-type and P-type transistors, respectively.

Operations of First Embodiment: Writing Operation to Memory Cell

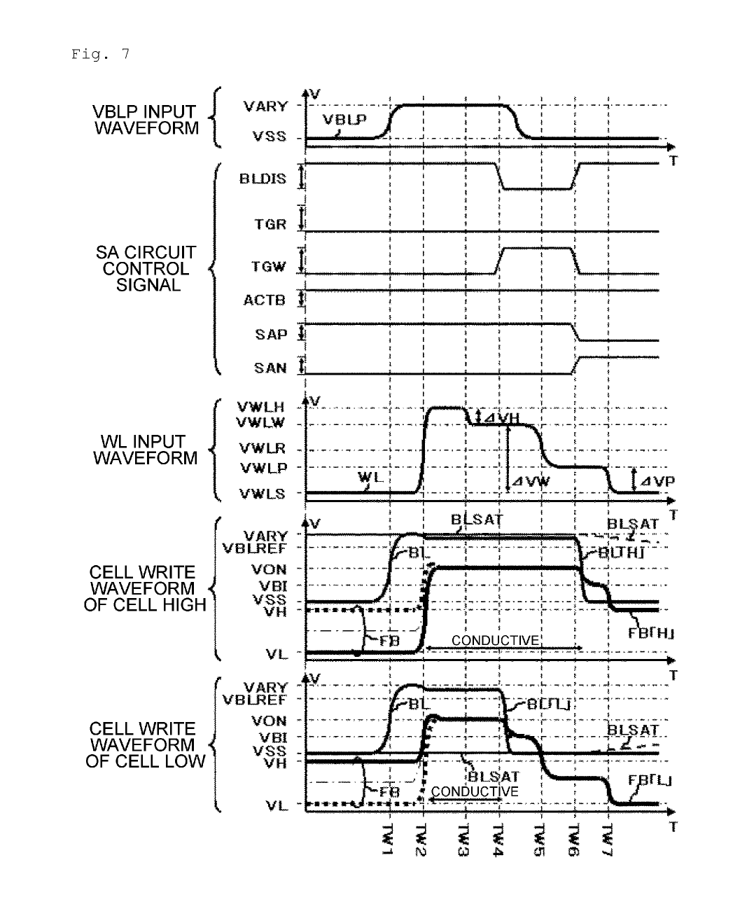

Next, operations of the first embodiment will be described. FIG. 7 is a view showing memory cell write waveforms according to the first embodiment. A writing operation to the memory cell 66 will now be described with reference to FIGS. 1 and 7.

In FIG. 7, a standby state, or in other words a state in which both the bit line BL, and the word line WL are unselected, is established up to a timing TW1. In this state, the bit line drive power supply signal VBLP is fixed at the VSS level, the bit line drive control signal BLDIS is fixed at the high level, and both. The control signals TGR and TGW are fixed at the low level. The bit line BL, meanwhile, is disconnected from the non-inverting sense amplifier bit line BLSAT and the inverting sense amplifier bit line BLSAB of the sense amplifier SA, and is therefore fixed at the low level (VSS). Further, the VARY voltage and the VSS voltage are supplied respectively to the power supply SAP and the power supply SAN used respectively for the P-type transistors and the N-type transistors of the flip flop F.F. of the sense amplifier SA such that the flip flop F.F. is activated, while the control signal ACTB is fixed at the high level, which corresponds to an inactive level. In this state, the flip flop F.F. holds write data input in advance from the non-inverting IO line IOT and the inverting IO line IOB. Accordingly, the voltage of the non-inverting sense amplifier bit line BLSAT at this time has an identical potential to the voltage VARY when The write data are at the high level, and has an identical potential to the voltage VSS when the write data are at the low level.

Further, the word line WL is fixed at the word line standby voltage VWLS, which corresponds to an unselected level. At this time, the FB node (corresponding to the P-body 3 in FIG. 6; see FIG. 3A) of the memory element (the thyristor) is at either a VH potential or a VL potential, depending on a logic level of the data held in the memory cell. The VH potential is higher than VL but lower than the built-in potential voltage VBI.

At the timing TW1, the bit line drive power supply signal VBLP is raised from the voltage VSS to the voltage VARY. The bit line drive control signal BLDIS is maintained at the high level, and therefore the voltage of the bit line BL also rises to the voltage VARY from the voltage VSS. At this stage, the voltage of the word line WL remains at the word line standby voltage VWLS even when the voltage of the bit line BL increases to VARY, which corresponds to the high level, and therefore the voltage of the FB node remains at the voltage prior to the timing TW1. Accordingly, the memory element is not operated.

At a timing TW2, the sub-word driver SWD increases the voltage, of the word line WL from the word line standby voltage VWLS to the word line overshoot voltage VWLH. Note that the level of the word line overshoot voltage VWLH is higher than that of the word line write, voltage VWLW by an amount corresponding to a voltage ΔVH. At this time, the voltage of the FB node is increased by the coupling of the capacitor C1 regardless of whether the high level or the low level is written to the memory cell. More specifically, the voltage of the FB node is increased via the capacitance of the cell capacitor to or above the built-in potential voltage VBI when the data held up to this point in the memory cell are at the high level VH, and to the vicinity of the built-in potential voltage VBI when the data are at the low level VL.

In particular, even when the low level is held in the memory cell, or in other words the FB node is at the VL level, prior no the timing TW1, the FB node is raised to a level that is higher by an amount corresponding to the voltage ΔVH at the timing TW2, and as a result of this increase, the thyristor becomes conductive quickly.

Furthermore, irrespective of the write data held by the flip flop F.F. of the sense amplifier SA, the bit line BL is driven to the high level (VARY), and therefore the thyristor enters the conductive state. When the thyristor enters the conductive state, the voltage of the bit line BL decreases slightly in accordance with an ON-resistance of the N-type transistor N1 and a resistance of the bit line BL. In addition, the FB node (see FIG. 3A) of the memory cell 66 is set at a voltage VON level that is determined by an ON-resistance of the PNP bipolar transistor Q2, characteristics of the PN junction diode (see FIG. 3) between the FB node and VSS (the cathode), and a ratio to a parasitic resistance or the like.

At a timing TW3, the sub-word driver SWD performs control to reduce the word line WL from the word line overshoot voltage VWLH to the word line write voltage VWLW.

At a timing TW4, the bit line drive control signal BLDIS is lowered from the high level to the low level, and the control signal TGW is raised from the low level to the high level. As a result, the bit line BL is connected to the non-inverting sense amplifier bit line BLSAT, and the voltage VARY continues to be supplied to the bit line voltage BL “H” used for writing the high level to the memory cell 66. Hence, the thyristor of the memory cell 66 remains in the conductive state. Meanwhile, the voltage VSS starts to be supplied to the bit line voltage BL “L” used for writing the low level to the memory cell, and therefore the thyristor of the memory cell 66 enters the non-conductive state. Further, the level, of the voltage FB “L” of the FB node of the memory cell decreases rapidly to the built-in potential voltage VBI due to the PN junction between the FB node (the P-type region) and the cathode VSS (the N-type region).

Note that after the timing TW4, the voltage level of the bit line drive power supply signal VBLP is lowered to the voltage VSS up to a timing TW6 at which the bit line drive control signal BLDIS is raised to the high level again.

At a timing TW5, the sub-word line driver SWD lowers the word line WL to the word line pre-charge voltage VWLP, which is an intermediate voltage between the word line write voltage VWLW and the word line standby voltage VWLS. When the high level is written to the memory cell, the bit line maintains the high level (VARY) so that the thyristor serving as the memory element remains in the conductive state, and therefore the voltage of the FB node remains at the voltage VON even though the voltage of the word line decreases to the word line pre-charge voltage VWLP.

On the other hand, when the data written to the memory cell are low level data and the voltage of the bit line BL is lowered. to the voltage VSS at the timing TW4, since the thyristor is already in the non-conductive state, the voltage of the FB node decreases to an even lower voltage than the built-in potential voltage VBI via the capacitance of the cell capacitor as the voltage of the word line WL decreases.

At a timing TW6, the control signal TGW fails such that The bit line BL is disconnected from the non-inverting sense amplifier bit line BLSAT, and the bit line drive, control signal BLDIS rises such that the voltage of the bit line BL is fixed at the voltage VSS, i.e. the voltage level of the bit line drive power supply signal VBLP. Further, the power supplies SAP and SAN of the flip flop F.F. of the sense amplifier SA are switched to the low level and the high level, respectively, thereby inactivating the flip flop F.F. From the timing TW6 onward, therefore, the non-inverting sense amplifier bit line BLSAT is in a floating state.

When the data written to the memory cell are high level data, the memory element constituted by the thyristor enters the non-conductive state and the level of the FB node decreases rapidly to the built-in potential voltage VBI as the voltage of the bit line EL decreases to VSS. When the data written to the memory cell are low level data, on the other hand, the voltage of the bit line BL is maintained at the low level (VSS), and therefore the state of the memory cell does not vary.

At a timing TW7, the sub-word driver SWD reduces the voltage of the word line WL from the word line pre-charge voltage VWLP to the word line standby voltage VWLS. Since the thyristor serving as the memory element is in the non-conductive state, the voltage of the FB node is also reduced via the capacitance of the cell capacitor. When the data written to the memory cell are high level data, the voltage of the FB node is reduced to the VH level, and when the written data are low level data, the voltage of the FB node is reduced even further to the VL level. A potential difference between VH and VL is held in the FB node as the data written to the memory cell.

As is evident from the above description, during the write operation, the memory element is made non-conductive as the voltage of the bit line BL is reduced to VSS, whereupon the FB node receives coupling of a voltage variation amount of the word line WL via the capacitance of the cell capacitor. Hence, the voltage of the FB node following the write operation can be represented as follows in a case where the written data are high level data and a case where the written data are low level data, respectively.

VH=VBI−ΔVP (1)

VL=VBI−ΔVW (2)

ΔVP is the potential difference between the word line pre-charge voltage VWLP and the word line standby voltage VWLS, and ΔVW is the potential difference between the word line write voltage VWLW and the word line standby voltage VWLS.

In the semiconductor device 30 according to the first embodiment, as described above, when the low level is written to the memory cell, the memory cell is made conductive for a period extending from the timing TW2 to the timing TW4, and in addition, The word line is caused to overshoot at the timing TW2. As a result, the memory cell can be made conductive quickly at the timing TW2 even when the low level is written to the memory cell. Therefore, a margin of an operation for rewriting low level data held in a memory cell with high level, data can be increased greatly.

Memory Cell Reading Operation

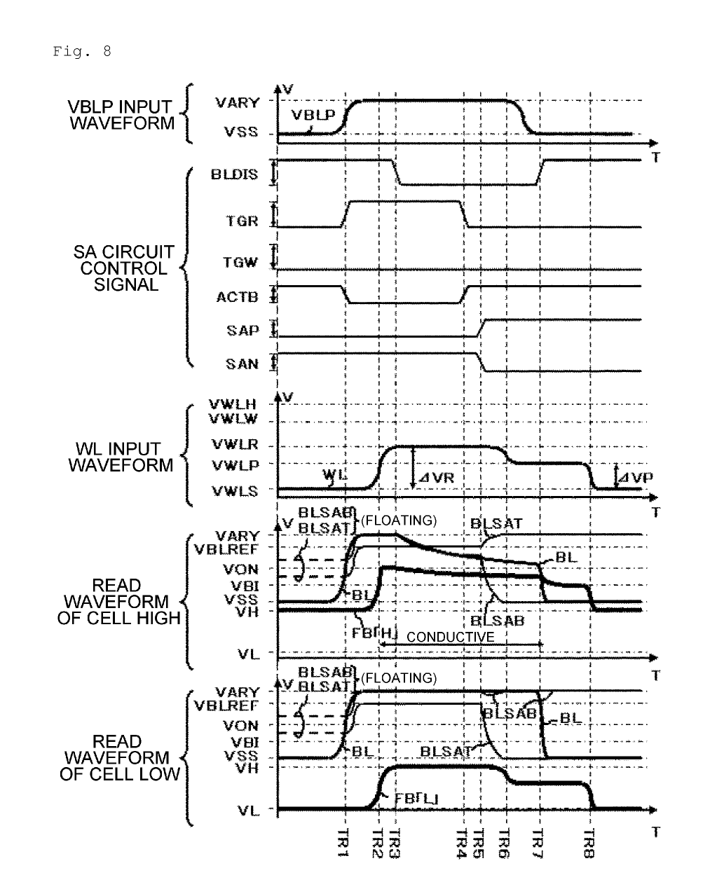

FIG. 8 is a view showing memory cell read waveforms according to the first embodiment. A reading operation to the memory cell will now be described with reference to FIGS. 1 and 8. A standby state, or in other words a state in which both the bit line BL and the word line WL are unselected, is established up to a timing TR1. In this state, the bit line drive power supply signal VBLP is fixed at the VSS level, the bit line drive control signal BLDIS is fixed. at the high level, and both the control signals TGR and TGW are fixed at The low level. The bit line BL, meanwhile, is disconnected from the non-inverting sense ampler bit line BLSAT and the inverting sense amplifier bit line BLSAB of The sense amplifier SA, and is therefore fixed. at the low level (VSS) by the N-type transistor N1.

Further, the power supply SAP and the power supply SAN used respectively for the P-type transistors and the N-type transistors of the flip flop F.F. of the sense amplifier SA are at the low level and the high level, respectively, such that the flip flop F.F. is in an inactive state, and the non-inverting sense amplifier bit line BLSAT and the inverting sense amplifier bit line BLSAB are both in the floating state. Note that the control signal ACTB is also at the high level, which corresponds to an inactive level. Furthermore, the FB node of the memory cell is assumed to be at either the VH level or the VL level, depending on the data held in the memory cell.

At the timing TR1, the bit line drive power supply signal VBLP is raised from the voltage VSS to the voltage VARY. The bit line, drive control signal BLDIS remains at the high level, and therefore the bit line BL is raised from the voltage VSS to the voltage VARY by the voltage output from the bit line drive power supply signal VBLP. Simultaneously, the control signal TGR is set at the high level so as to be activated, whereby the inverting sense amplifier bit line BLSAB is connected to the bit line BL, and therefore the voltage of the inverting sense amplifier bit line BLSAB also increases to the voltage VARY. Furthermore, the control signal ACTB falls to the low level so as to be activated, and therefore the voltage of the non-inverting sense amplifier bit line BLSAT becomes equal to the bit line reference voltage VBLREF.

At a timing TR2, the sub-word driver SWD increases the voltage of the word line WL to the word line read voltage VWLR. The word line read voltage VWLR is lower than the word line write voltage VWLW but higher than the word line pre-charge voltage VWLP. By raising the voltage of the word line to the word line read voltage VWLR at the timing TR2, the voltage of the FB node is also increased via the capacitance of the capacitor of the memory cell. When the memory cell holds the high level and the voltage of the FB node is at the VH level, the voltage of the FB node is increased to the built-in potential voltage VBI at which the memory element (the thyristor) enters the conductive state by the rise of the word line, and as a result, the memory element enters the conductive state. When the memory cell holds the low level and the voltage of the FB node is at the VL level, on the other hand, the voltage of the FB node is increased by the rise of the word line but not to the built-in potential voltage VBI at which the memory element (the thyristor) enters the conductive state. The memory element does not therefore enter the conductive state.

At a timing TR3, the bit line drive control signal BLDIS is lowered to the low level, and the bit line BL is released from the voltage VARY. The inverting sense amplifier bit line BLSAB is connected to the bit line BL via the N-type transistor N2, and therefore, when the memory element (the thyristor) of the memory cell is conductive, the respective voltages of the bit line BL and the inverting sense amplifier bit line BLSAB decrease gradually. When the memory element (the thyristor) is not conductive, on the other hand, a current flow route does not exist, and therefore the respective voltages of the bit line BL and the inverting sense amplifier bit line BLSAB remain at the voltage VARY. Note that the non-inverting sense amplifier his line BLSAT is maintained at the bit line reference voltage VBLREF via the P-type transistor P2. In addition, after the timing TR3, the voltage level of the bit line drive power supply signal VBLP is lowered from the voltage VARY to the voltage VSS up to a timing TR7, at which the bit line drive control signal BLDIS rises to the high level again.

At a timing TR4, the control signal TGR is lowered to the low level in order to disconnect the bit line BL from the inverting sense amplifier his line BLSAB. Simultaneously, the read control signal ACTB is raised to the high level in order to disconnect the non-inverting sense amplifier bit line BLSAT from the his line reference voltage VBLREF.

Next, at a timing TR5, the power supplies SAP and SAN used respectively for the P-type and N-type transistors of the flip flop F.F. of the sense amplifier SA are set at the high level (VARY) and the low level (VSS), respectively, in order to activate the flip flop F.F. Accordingly, the flip flop F.F. starts to amplify the potential difference between the non-inverting sense amplifier bit line BLSAT and the inverting sense amplifier bit line BLSAB. Here, when the memory cell holds the high level and the memory element, is made conductive, by the rise of the word. line WL, the voltage of the inverting sense amplifier bit line BLSAB decreases to a voltage no greater than the bit line reference voltage VBLREF, and therefore the non-inverting sense amplifier bit line BLSAT and the inverting sense amplifier bit line BLSAB are amplified to the high level and the low level, respectively. Conversely, when the memory cell holds the low level and the memory element is not made conductive by the rise of the word line WL the voltage of the inverting sense amplifier bit line BLSAB remains at the voltage VARY, and therefore the non-inverting sense amplifier bit line BLSAT and the inverting sense amplifier bit line BLSAB are amplified to the low level and the high level, respectively.

At a timing TR6, the sub-word driver SWD reduces the voltage, of the word line WL from the word. line read voltage. VWLP so the word line pre-charge voltage VWLP. When the memory cell holds the high level, the voltage of the bit line BL decreases gradually, but since the memory element (the thyristor) is still conductive, the PNP transistor Q2 (see FIG. 3A) remains ON, and therefore the voltage of the FB node remains at or above the built-in potential voltage VBI. When the memory cell holds the low level, on the other hand, the memory element (the thyristor) is not conductive, and therefore the voltage of the FB node decreases as the voltage of the word line WL decreases via the capacitance of the capacitor of the memory cell.

At the timing TR7, the bit line drive control signal BLDIS is raised, and the voltage of the bit line BL is fixed at the low level (VSS). When the memory cell holds the high level, the memory element (the thyristor) enters the non-conductive state such that the level of the FB node decreases rapidly to the built-in potential voltage VBI. When the memory cell holds the low level, on the other hand, the memory element remains in the non-conductive state, and therefore the voltage of the FB node does not vary.

At a timing TR8, the sub-word driver SWD reduces the voltage of the word line ML from the word line pre-charge voltage VWLP to the word line standby voltage VWLS. Since the memory element (the thyristor) is in the non-conductive state, the voltage of the FB node also decreases via the capacitance of the cell capacitor. When the data written to the memory cell are high level data, the voltage of the FE node is reduced to a voltage shown in Equation (1), or in other words to the VH level, and when the written data are low level data, the voltage of the FB node is reduced to the VL level, which is the voltage thereof prior to the timing TR1. In other words, the data in the memory cell before the reading operation are held even after the reading operation.

Note that when the operations of the semiconductor device 30 are compatible with a DRAM, memory cell reading control and memory cell writing control are performed in response to an ACT command and a PRE command, respectively, Further, the data in the F.F. of the sense amplifier SA are read in response to a read command, and write data are written to the F.F. of the sense amplifier SA in response to a write command. During a refresh operation, cell reading control is performed in response to a refresh command, and memory cell write control is performed from the timing TW1 immediately after the timing TR8. Furthermore, according to DRAM specifications, a fixed time known as tRFC (between approximately 100 ns and 260 ns) exists between input of the refresh command and permission to input the next command, such as the ACT command.

Next, the refresh operation performed by the semiconductor device 30 according to the first embodiment will be described. In a semiconductor device that stores a charge in a floating body, such as the semiconductor device 30 according to the first embodiment, the voltage of the FB node of a memory cell connected to a periodically inactive word line is unstable. When a memory cell having an FB node with an unstable voltage exists, a reading defect may occur in another memory cell. In the semiconductor device 30, therefore, control is performed during The refresh operation performed in response to the refresh command to activate used word lines and unused word lines sequentially, and write a predetermined voltage to the FB nodes of the memory cells connected to These word lines.

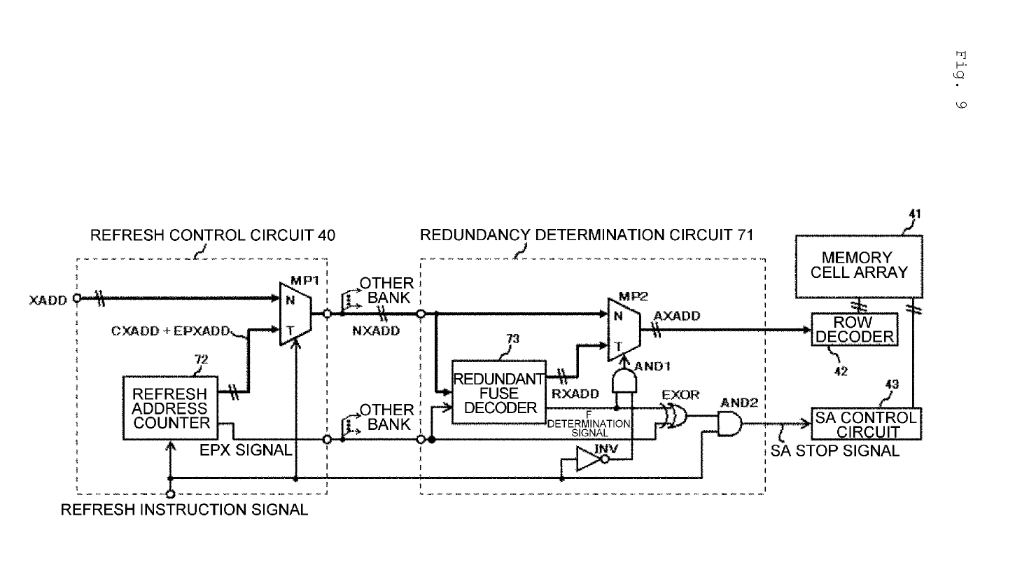

FIG. 9 is a view showing detailed examples of circuit configurations of the refresh control circuit 40 and the redundancy determination circuit 71 of the semiconductor device 30 shown in FIG. 2. Control performed by the refresh control circuit 40 on the row decoder 42, the SA control circuit 43, and the memory cell array 41 will now be described with reference to FIG. 9.

The refresh control circuit 40 is configured to include a refresh address counter 72 that outputs a refresh address CXADD+EPXADD, and a multiplexer MP1. When a refresh instruction signal is activated, the refresh address counter 72 repeatedly counts both a normal refresh address CXADD and an extended refresh address EPXADD. The normal refresh address CXADD includes the number of addresses required to select each used word line once, and the extended refresh address EPXADD includes the number of addresses required to select each unused word line once. Note that the extended refresh address EPXADD is allocated to the respective redundant word lines and dummy word lines so that a desired redundant word line or dummy word line can be selected using the extended refresh address EPXADD.

For example, the number of refresh operations required to activate all of the used word lines in the memory array of a single bank once is set at 4096 (=2̂12), the number of refresh operations required to activate all of the redundant word lines once is set at 32, and the number of refresh operations required to activate all of the dummy word lines once is set at 64. The refresh address counter 72 counts up from 0 every time the refresh instruction signal is activated, and after reaching 4191 (=4096+32+64−1), returns the count value to 0 when the next refresh instruction signal is activated, whereupon the counting operation is repeated. In this case, count values from 0 to 4095 correspond to the normal refresh address CXADD, and count values from 4096 to 4191 correspond to the extended refresh address EPXADD. Further, during a period in which the refresh address counter 72 outputs the extended refresh address EPXADD, an extended address flag signal EPX is activated. Note that in this example, 4191 is less than 2¹³, and therefore the number of address signal lines of the refresh address CXADD+EPXADD is 13.

The multiplexer MP1 outputs an external input address XADD during the reading and writing operations, and during the refresh operation (when the refresh instruction signal is activated) outputs the refresh address CXADD+EPXADD as an internal X address NXADD.

By allocating addresses to the used word lines and unused word lines in accordance with the internal X address NXADD, a predetermined voltage, or in other words the VH or VL potential, can be written at fixed period intervals to the FB nodes of all of the memory cells of the semiconductor device 30 that are connected to both the used word lines and the unused word lines during the refresh operation.

In the semiconductor device 30 according to the first embodiment, a predetermined voltage, or in other words the VH or VL potential, is written at fixed period intervals to the FB nodes of all of the memory cells of the semiconductor device 30 that are connected to both the used word lines and the unused word lines during the refresh operation, and therefore data reading defects do not occur. In the semiconductor device 30, the level of the FB node of a memory cell that has not been accessed for a long time is unstable due to a slight leakage current. Hence, the level of the FB node of the memory cell may be close to the voltage VSS. Accordingly, when data are read from the memory cell and the selected word line is increased from the word line standby voltage VWLS to the word line read voltage VWLR, the potential of an unselected word line is affected by noise from an adjacent coupling to the selected word line.

More specifically, the potential of the unselected word line increases slightly from the word line standby voltage VWLS.

As a result, the potential of the FB node of the memory cell connected to the unselected word line also increases slightly. When the potential of the FB node of the memory cell increases to the built-in potential voltage VBI, the memory cell becomes conductive. However, the memory cell connected to the unselected word line is an unselected cell, and therefore the memory cell must not be made conductive while another cell is being accessed, even when the bit line connected thereto is activated. When the memory cell that must not be made conductive becomes conductive, the bit line voltage BL decreases, causing a reading defect.

In the semiconductor device 30 according to the first embodiment, on the other hand, the FB nodes of all memory cells, including the memory cells connected to the unused word lines, are set at the predetermined voltage at fixed period intervals during the refresh operation, and therefore an FB node having a high voltage cannot exist during the reading operation. As a result, the reading defect described above does not occur.

### Second Embodiment

Next, a second embodiment will be described in detail with reference to the drawings. No differences exist in the overall configurations of the semiconductor device 30 according to the first embodiment and a semiconductor device 30a according to the second embodiment, and therefore description corresponding to FIG. 2 has been omitted in relation to the semiconductor device 30a. The semiconductor device 30a differs from the semiconductor device 30 in that during refresh control, the cell Low is written to the FB node of the memory cell.

On unused word lines such as replaced normal word lines that are replaced in a redundancy replacement process and dummy word lines at the ends of the cell region, the leakage current of the FB node may be larger than in inside memory cells. Hence, by writing the cell Low (FB node: VL potential) instead of the cell High (FB node: VH potential) to the memory cells connected to the unused word lines, a longer leakage time is required for the memory cells to reach a level close to VSS, at which the memory cells become erroneously conductive as described above, leading to an improvement in the refresh characteristic of the unused word lines. In the semiconductor device 30a according to the second embodiment, therefore, the cell Low is written to the FB nodes of the memory cells when a refresh operation is performed on the unused word lines.

The redundancy determination circuit 71 shown in FIG. 9 is disposed in each bank. The redundancy determination circuit 71 is configured to include a redundant fuse decoder 73, a multiplexer MP2, AND circuits AND1 and AND2, an exclusive OR circuit EXOR, and an inverter circuit INV.

The multiplexer MP2 outputs an array portion X address AXADD . When the extended address flag signal EPX is inactive (in the case of the normal refresh address CXADD), the redundant fuse decoder 73 determines whether or not the internal X address NXADD is an address replaced by a redundant word line. More specifically, when the internal X address NXADD is an address replaced by a redundant word line, the redundant fuse decoder 73 outputs a corresponding redundant word line address RXADD and activates an F determination signal. Note that the internal X address NXADD is determined to be an address replaced by a redundant word line when the internal X address NXADD matches an address written to the redundant fuse decoder 73. When the extended address flag signal EPX signal is active (in the case of the extended refresh address EPXADD), the redundant fuse decoder 73 activates the F determination signal in a case where the redundant word line corresponding to the extended refresh address EPXADD has been replaced and is in use, and deactivates the F determination signal in a case where the corresponding redundant word line has not been replaced and is not in use, or in a case where the corresponding word line is a dummy word line.

When the refresh instruction signal is inactive, the refresh control circuit 40 instructs the row decoder 42 and the SA control circuit 43 to perform an operation to read or write data from or to the memory cell. In this case, a normal word line that has not been replaced by redundancy or a redundant word line that has been replaced and is in use is selected in accordance with a redundancy determination result from the redundant fuse decoder 73. More specifically, when a normal word line that has not been replaced by redundancy is used, the array portion X address AXADD output from the redundancy determination circuit 71 is the external input address XADD itself. When a redundant word line that has been replaced and is in use is used, the array portion X address AXADD output from the redundancy determination circuit 71 is a redundant word line address RXADD specifying one of the redundant word lines RedWL. Note that when the refresh instruction signal is inactive, the extended address flag signal EPX is inactive, and therefore the SA stop signal is inactive (the operations of the sense amplifiers are not stopped).

When the refresh instruction signal is active, the refresh control circuit 40 instructs the row decoder 42 and the SA control circuit 43 to perform the refresh operation. During the refresh operation, the refresh address CXADD+EPXADD is output as the array portion X address AXADD output from the redundancy determination circuit 71, regardless of the redundancy determination result. Further, when the extended address flag signal EPX is inactive and the F determination signal is active during the refresh operation, the internal X address NXADD indicates an unused word line replaced by redundancy, and therefore the SA stop signal is activated (the operations of the sense amplifiers are stopped). Likewise when the extended address flag signal EPX is active and the F determination signal is inactive during the refresh operation, the corresponding redundant word line is unused, and therefore the SA stop signal is activated. Note that when these conditions are not satisfied, the SA stop signal is inactive (the operations of the sense amplifiers are not stopped).

As described above, when an unused word line is selected during the refresh operation, the SA stop signal is activated. When the SA stop signal is activated, the SA control circuit 43 performs an operation to write the cell Low forcibly to the FB node of the memory cell connected to the selected word line (an unused word line).

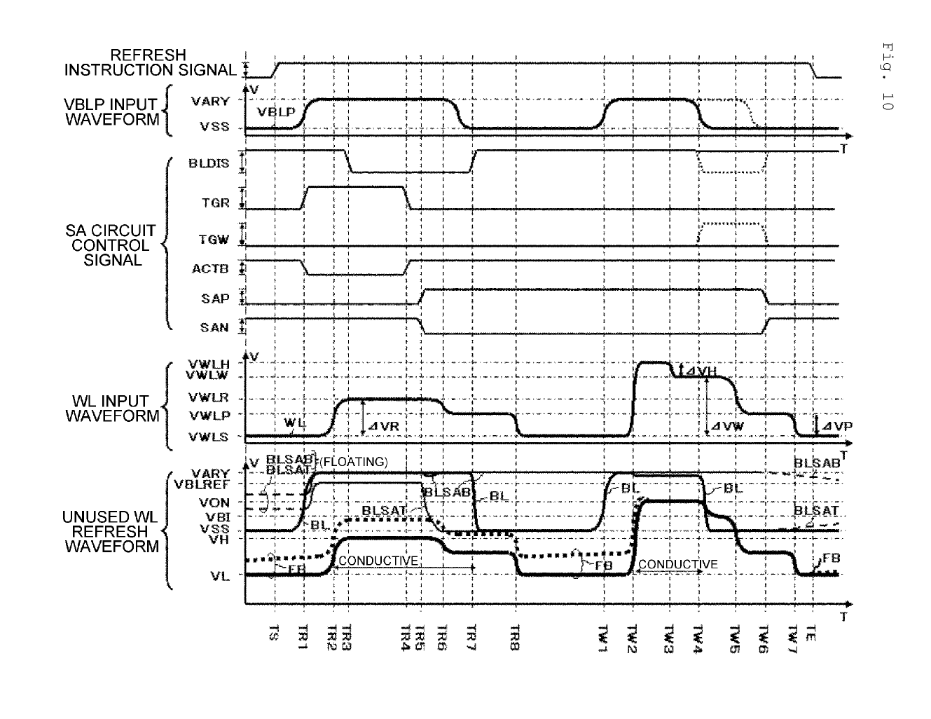

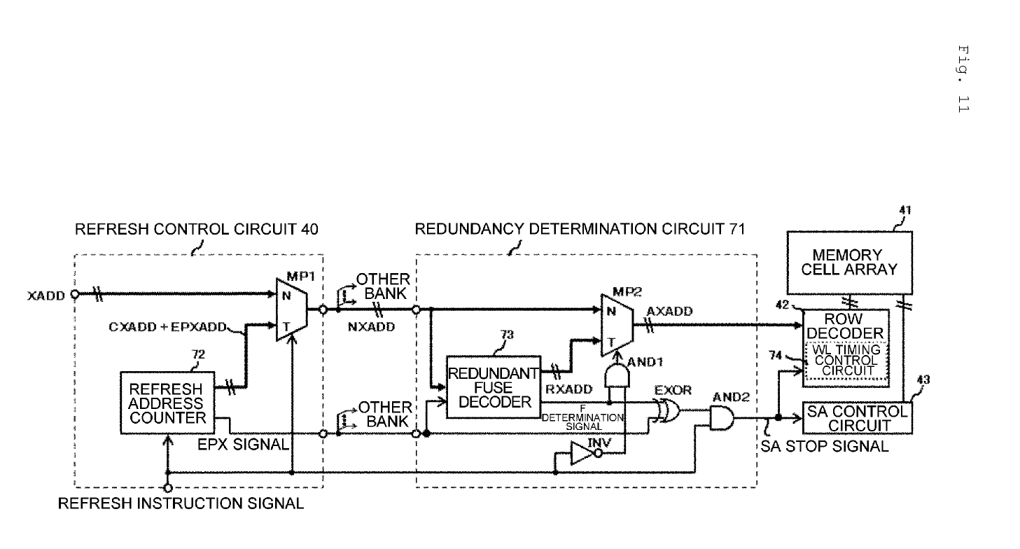

FIG. 10 is a view showing examples of waveforms generated during the refresh operation performed by the semiconductor device 30a according to the second embodiment.

At a timing TS in FIG. 10, the refresh instruction signal is activated from the low level to the high level. Note that from a timing TR1 to a timing TR8, identical waveforms to the memory cell read waveforms shown in FIG. 8 are generated, and therefore further description thereof has been omitted. Moreover, from a timing TW1 to a timing TW7, dotted line waveforms of the bit line drive power supply signal VBLP, the bit line drive control signal BLDIS, and the control signal TGW are similar to the memory cell write waveforms shown in FIG. 7, and these dotted line waveforms denote refresh control waveforms generated when the SA stop signal is inactive, or in other words when a used word line is refreshed. Therefore, description of the dotted line waveforms from the timing TW1 to the timing TW7 has been omitted.

Solid line waveforms of the bit line drive power supply signal VBLP, the bit line drive control signal BLDIS, and the control signal TGW from the timing TW1 to the timing TW7 in FIG. 10 are refresh control waveforms generated when the SA stop signal is active, or in other words when an unused word line is refreshed.

At the timing TW4, the bit line drive power supply signal VBLP falls from the voltage VARY to the voltage VSS. Further, the bit line drive control signal BLDIS and the control signal TGW are maintained at the high level and the low level, respectively, such that the bit line drive power supply signal VBLP is supplied to the bit line BL, and as a result, the bit line BL falls to VSS. This operation of the bit line BL is identical to a “cell Low write waveform” of the memory cell write waveform diagram shown in FIG. 7. As a result of this operation, the cell Low is forcibly written to the FB node of the memory cell connected to the unused word line.

At a timing TE, the refresh instruction signal is switched from the high level to the low level so as to be deactivated, whereby the refresh operation is terminated. An FB node indicated by a dotted line in FIG. 10 denotes a cell having a large leakage current, and therefore this FB node has a higher voltage than the VL potential at a timing TS immediately prior to the refresh operation. It can be seen, however, that at the timing TE, upon completion of the refresh operation, the voltage of the FB node has decreased to the VL potential.

With the semiconductor device 30a according to the second embodiment, as described above, when an unused word line is selected during the refresh operation, the cell Low can be written forcibly to the FB node of the memory cell. Moreover, circuits required at this time can be realized by a comparatively simple circuit configuration.

### Third Embodiment

A third embodiment will now be described in detail with reference to the drawings. No differences exist in the overall configurations of the semiconductor device 30 according to the first embodiment and a semiconductor device 30b according to the third embodiment, and therefore description corresponding to FIG. 2 has been omitted in relation to the semiconductor device 30b.

When an unused word line is refreshed, the semiconductor device 30b according to the third embodiment writes an even lower voltage than the VL potential serving as the cell Low to the FB node of the memory cell connected to the unused word line, thereby further improving the refresh characteristic of the unused word line. Moreover, a current consumption during refreshing of the unused word line is reduced.

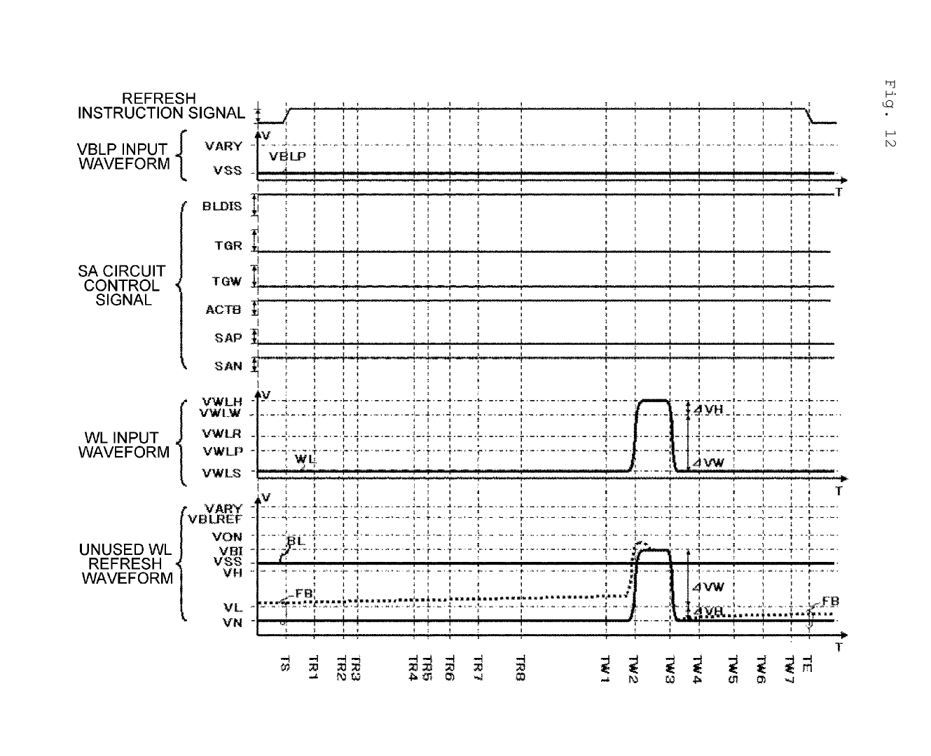

FIG. 11 is a view showing detailed examples of circuit configurations of the refresh control circuit 40 and the redundancy determination circuit 71 of the semiconductor device 30b according to the third embodiment. Control of the row decoder 42, the SA control circuit 43, and the memory array 41 will now be described with reference to FIG. 11. Note that in FIG. 11, identical constituent elements to FIG. 9 have been allocated identical reference symbols, and description thereof has been omitted.

FIG. 11 differs from FIG. 9 in that the row decoder 42 includes a WL timing control circuit 74 that receives the SA stop signal. As described above using FIG. 9, the SA stop signal output by the redundancy determination circuit 71 is activated when an unused word line is selected during the refresh operation. In the semiconductor device 30b according to this embodiment, refresh control performed in relation to an unused word line differs from refresh control performed in relation to a used word line.

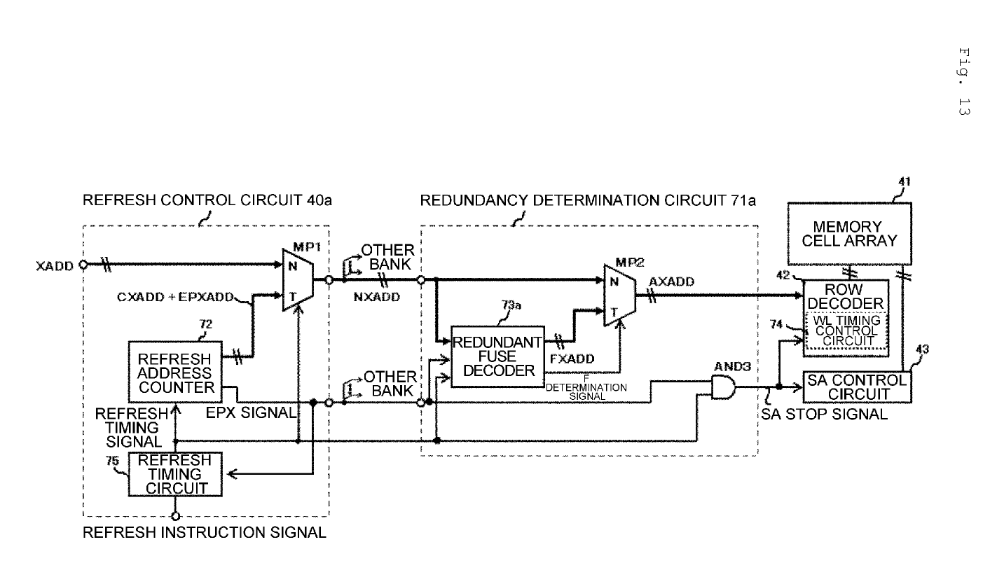

FIG. 12 is a view showing examples of refresh control waveforms generated by the semiconductor device 30b in relation to an unused word line. In FIG. 12, it is assumed that the SA stop signal is activated (i.e. that an unused word line is selected) for a period extending from a timing TR1 to a timing TW7.

At a timing TS, the refresh instruction signal is switched from the low level to the high level and thereby activated. At this time, an FB node indicated by a dotted line belongs to a cell having a large leakage current, and therefore this FB node has a higher voltage than an FB node indicated by a solid line, which belongs to a cell having substantially no leakage current.

From the timing TR1 to the timing TW7, the SA control circuit 43, under the influence of the activated SA stop signal, stops all operations of the bit line drive power supply signal VBLP and the SA circuit control signals (BLDIS and so on). As a result, the standby state established before the timing TR1 is maintained. During this period, the bit line drive power supply signal VBLP is maintained at VSS and the bit line drive control signal BLDIS is maintained at the high level, and therefore VSS continues to be supplied to the bit line BL.

The WL timing control circuit 74, under the influence of the activated SA stop signal, holds the word line WL at the word line standby voltage VWLS until a timing TW2. Then, at the timing TW2, the WL timing control circuit 74 increases the word line WL from the word line standby voltage VWLS to the word line overshoot voltage VWLH. An amplitude at this time is ΔVW+ΔVH. At this time, the voltage of the FB node is increased by a level corresponding substantially to ΔVW+ΔVH by the coupling of the capacitor C1. In other words, an FB node indicted by a solid line in FIG. 12 increases to the vicinity of the built-in potential voltage VBI, while an FB node indicated by a dotted line increases momentarily above the built-in potential voltage VBI but then decreases rapidly to the built-in potential voltage VBI.

At a timing TW3, the WL timing control circuit 74 reduces the word line WL from the word line overshoot voltage VWLH to the word line standby voltage VWLS. At this time, the voltage of the FB node is reduced to a VN level, which is even lower than the VL level (the voltage of the FB node of the cell Low) by the coupling of the capacitor C1. The VN level can be expressed by Equation (3), shown below.

VN=VBI−(ΔVW+ΔVH) (3)

After the timing TW3, the WL timing control circuit 74 holds the word line WL at the word line standby voltage VWLS. Then, at a timing TE, the refresh instruction signal is switched from the high level to the low level so as to be deactivated, and as a result, the refresh operation is terminated.

As described above, when the SA stop signal is activated, the SA control circuit 43 stops the operations of the sense amplifiers. Furthermore, while the bit line BL is held at the voltage VSS, the WL timing control circuit 74 increases the word line WL from the word line standby voltage VWLS to the word line overshoot voltage VWLH, and then reduces the word line WL to the word line standby voltage VWLS. As a result, the voltage of the FB node decreases to the VN level that is even lower than the VL level.

When the refresh operation is performed on an unused word line by the semiconductor device 30b according to the third embodiment, the FB node of the cell connected to the unused word line is reduced to the VN potential that is even lower than VL. As a result, the refresh characteristic of the unused word line can be improved even further. Moreover, when the refresh operation is performed on an unused word line, the SA control circuit 43 is stopped completely and word line control is simplified, and therefore the current consumption can be reduced.

Note that in the waveform examples shown in FIG. 12, the potential of the word line is increased during the period extending from the timing TW2 to the timing TW3, but the period for increasing the potential of the word line is not limited to this period. Further, in the waveform examples shown in FIG. 12, the word line overshoot voltage VWLH is used as the high level of the word line, but the high level of the word line is not limited to this voltage, and the voltage of the FB node can be reduced to the VN level that is even lower than the VL level (the voltage of the FB node of the cell Low) as long as the high level of the word line is a higher voltage than the word line write voltage VWLW. It goes without saying that by increasing the word line to an even higher voltage than the word line overshoot voltage VWLH, the voltage of the FB node following the refresh operation performed on the unused word line can be set at an even lower level than the VN level, and as a result, the refresh characteristic of the unused word line can be improved yet further.

### Fourth Embodiment

Next, a fourth embodiment will be described in detail with reference to the drawings. No differences exist in the overall configurations of the semiconductor device 30 according to the first embodiment and a semiconductor device 30c according to the fourth embodiment, and therefore description corresponding to FIG. 2 has been omitted in relation to the semiconductor device 30c.

In the semiconductor device 30c according to the fourth embodiment, a plurality of unused word lines are respectively refreshed continuously over a plurality of short cycles within the period (a single tRFC period according to DRAM specifications) between input of the refresh command and permission to input the next command, such as the ACT command.

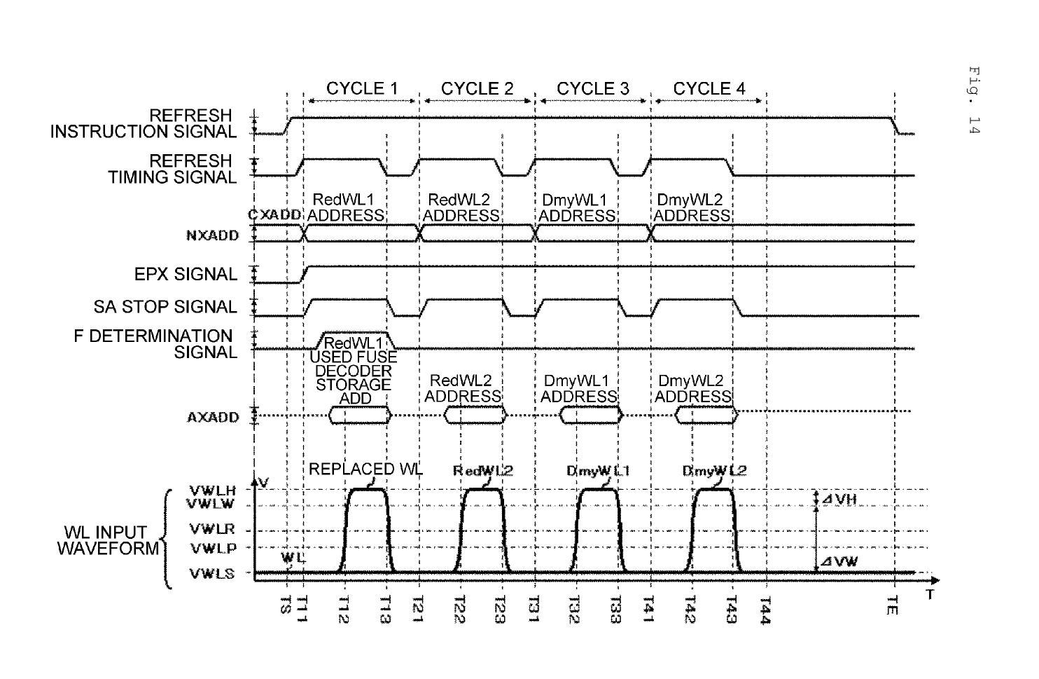

FIG. 13 is a view showing detailed examples of circuit configurations of a refresh control circuit 40a and a redundancy determination circuit 71a of the semiconductor device 30c according to the fourth embodiment. Control of the row decoder 42, the SA control circuit 43, and the memory array 41 will now be described with reference to FIG. 13. Note that in FIG. 13, identical constituent elements to FIG. 11 have been allocated identical reference symbols, and description thereof has been omitted.

On a circuit shown in FIG. 13, internal configurations of the refresh control circuit 40a and the redundancy determination circuit 71a differ from the circuit shown in FIG. 11. The refresh control circuit 40a further includes a refresh timing circuit 75. The refresh timing circuit 75 receives the extended address flag signal EPX signal and the refresh instruction signal, and outputs a refresh timing signal. Note that the refresh address counter 72 included in the refresh control circuit 40a has identical functions to the circuit included in the refresh control circuit 40, but differs therefrom in that counting up is performed on the basis of the refresh timing signal.

The redundancy determination circuit 71a is configured to include a redundant fuse decoder 73a, the multiplexer MP2, and an AND circuit AND3. The refresh timing signal is also input into the redundant fuse decoder 73a. The redundant fuse decoder 73a outputs a fuse decoder output address FXADD.

When the refresh instruction signal is inactive and a determination result from the redundant fuse decoder 73a is not an address replaced by a redundant word line (in other words, when the internal X address NXADD does not match the address written to the redundant fuse decoder 73a), an external input address XADD is output from the redundancy determination circuit 71a as the array portion X address AXADD, and a normal word line is selected. Further, when the determination result from the redundant fuse decoder 73a is an address replaced by a redundant word line (in other words, when the internal X address NXADD matches the address written to the redundant fuse decoder 73a), the redundant word line address RXADD is output as the array portion X address AXADD, and a redundant word line is selected.

When the refresh instruction signal is active while the refresh address counter 72 counts the normal refresh address CXADD, or in other words while the extended address flag signal EPX signal is at the low level, and the determination result from the redundant fuse decoder 73a is not an address replaced by a redundant word line, the normal refresh address CXADD is output from the redundancy determination circuit 71a as the array portion X address AXADD, and a normal word line is selected. Further, when the determination result from the redundant fuse decoder 73a is an address replaced by a redundant word line while the refresh address counter 72 counts the normal refresh address CXADD, the redundant word line address RXADD is output as the array portion X address AXADD, and a redundant word line is selected. In other words, in both cases the selected redundant word line is a used word line. Furthermore, the WL timing control circuit 74, the SA control circuit 43, and so on implement normal refresh control (the control indicated by dotted lines in FIG. 10, which was described using FIGS. 7 and 8).

When the refresh instruction signal is active while the refresh address counter 72 counts the extended refresh address EPXADD, or in other words while the extended address flag signal EPX signal is at the high level, and the redundant word line corresponding to the extended refresh address EPXADD in the redundant fuse decoder 73a is an unused word line that has not been replaced or a dummy word line, the F determination signal becomes inactive and the internal X address NXADD (in other words, the extended refresh address EPXADD) is output as the array portion X address AXADD. The extended refresh address EPXADD in this case indicates an unused redundant word line that has not been replaced or a dummy word line, and therefore an unused word line is selected. Further, when the refresh instruction signal is active while the refresh address counter 72 counts the extended refresh address EPXADD, or in other words while the extended address flag signal EPX signal is at the high level, and the redundant word line corresponding to the extended refresh address EPXADD in the redundant fuse decoder 73a is a used word line that has been replaced, the redundant fuse decoder 73a activates the F determination signal and outputs a replacement address stored therein as the fuse decoder output address FXADD. In other words, the fuse decoder output address FXADD is the address of a replaced normal word line replaced in a redundancy replacement process, and therefore indicates an unused word line. The fuse decoder output address FXADD is output as the array portion X address AXADD. Hence, when the refresh instruction signal is active while the refresh address counter 72 counts the extended refresh address EPXADD, or in other words while the extended address flag signal EPX signal is at the high level, an unused word line is selected.

By configuring the refresh control circuit 40a and the redundancy determination circuit 71a as shown in FIG. 13, a used word line is selected during the refresh operation when the extended address flag signal EPX signal is at the low level, and an unused word line is selected when the extended address flag signal EPX signal is at the high level.

When the extended address flag signal EPX signal is activated, the refresh timing circuit 75 included in the refresh control circuit 40a outputs a plurality of refresh timing signal for every refresh instruction signal.

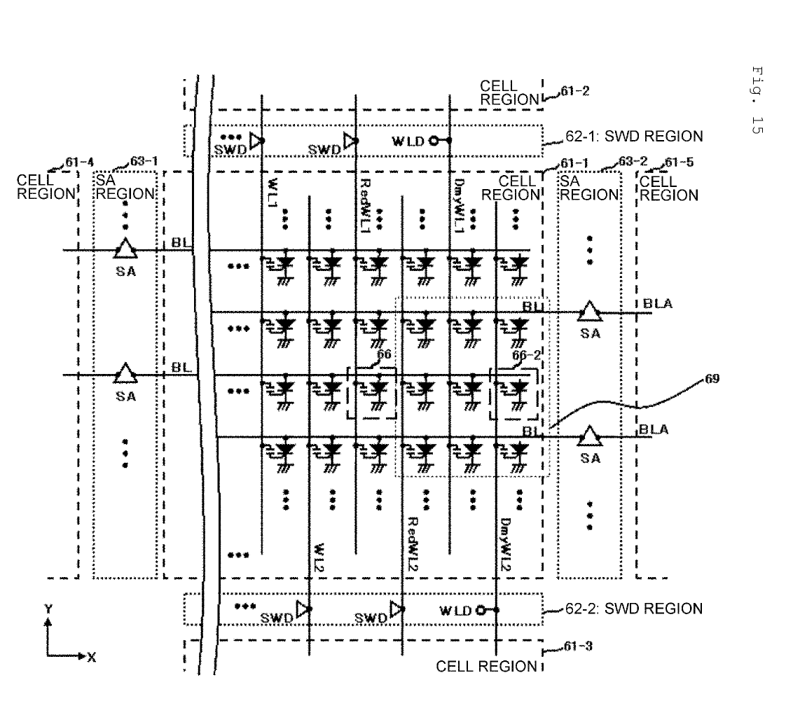

FIG. 14 is a view showing examples of waveforms generated when the extended address flag signal EPX signal is activated during refreshing. It is assumed that before a timing TS, the count value of the refresh address counter indicates the normal refresh address CXADD.

At the timing TS, the refresh instruction signal is switched from the low level to the high level and thereby activated. At a timing T11, the refresh timing circuit 75, having received the activated refresh instruction signal, activates the refresh timing signal. In accordance with activation of the refresh timing signal, the refresh address counter 72 counts up. In the example shown in FIG. 14, the count value switches to the extended refresh address EPXADD, and the extended address flag signal EPX signal is activated.

A period extending from the timing T11 to a timing T21 corresponds to cycle 1. In the example shown in FIG. 14, the internal X address NXADD of cycle 1 is the address of the redundant word line RedWL1, and the redundant word line RedWL1 is an operative redundant word line that has been replaced. At this time, the F determination signal is activated, and the address stored in the redundant fuse decoder 73 is output as the array portion X address AXADD. Furthermore, the SA stop signal is generated by performing a logical AND operation on the refresh timing signal and the extended address flag signal EPX signal, and is therefore activated at the timing T11. When the SA stop signal is activated, the WL timing control circuit 74 performs control to operate the word line in a single shot. More specifically, the word line is raised at the timing T12 and lowered at a timing T13. Meanwhile, the replaced word line specified by the array portion X address AXADD is activated. In the example shown in FIG. 14, similarly to the third embodiment, the inactive level of the word line is the word line standby voltage VWLS, the active level of the word line is the word line overshoot voltage VWLH, and the voltage of the FB node of the cell connected to the replaced word line decreases to the VN level (see FIG. 10). Further, the refresh timing circuit 75 deactivates the refresh timing signal at the timing T13, and reactivates the refresh timing signal at the following timing T21.

A period extending from the timing T21 to a timing T31 corresponds to cycle 2. In this example, the internal X address NXADD in cycle 2 is the address of the redundant word line RedWL2, and the redundant word line RedWL2 is an unused redundant word line that is not in use. Since the redundant word line RedWL2 is not an operative redundant word line that has been replaced, the F determination signal output by the redundant fuse decoder 73a is inactive. Accordingly, the array portion X address AXADD matches the address of the redundant word line RedWL2. Since the SA stop signal is active, the WL timing control circuit 74 performs control to operate the word line in a single shot. More specifically, the word line is raised at a timing T22 and lowered at a timing T23. Meanwhile, the redundant word line RedWL2 specified by the array portion X address AXADD is active.

A period extending from the timing T31 to a timing T41 corresponds to cycle 3. In this example, the internal X address NXADD in cycle 3 is the address of the dummy word line DmyWL1. When the internal X address NXADD indicates the dummy word line DmyWL1, the F determination signal is inactive. Accordingly, the array portion X address AXADD matches the address of the dummy word line DmyWL1. Since the SA stop signal is activated, the WL timing control circuit 74 performs control to operate the word line in a single shot. More specifically, the word line is raised at a timing T32 and lowered at a timing T33. Meanwhile, the dummy word line DmyWL1 specified by the array portion X address AXADD is active.

A period extending from the timing T41 to a timing T44 corresponds to cycle 4. Likewise in cycle 4, similarly to cycle 3, the dummy word line DmyWL2 is activated for a period extending from a timing T42 to a timing T43.

In the example shown in FIG. 14, unused word lines at four addresses are refreshed in four cycles within a single tRFC period prescribed by DRAM specifications. In other words, when the extended address flag signal EPX signal is activated, a plurality of unused word lines are activated consecutively during a single tRFC period, and the unused word lines are refreshed. Note that the number of cycles (four cycles) may be set at an appropriate number of cycles in accordance with a relationship between tRFC time specifications and the time required for a single cycle. Further, the refresh timing circuit 75 counts the number of cycles while the extended address flag signal EPX signal is active. Furthermore, the number of cycles is preferably set at a factor of the number of extended refresh addresses EPXADD. The purpose of this is to prevent the extended refresh address EPXADD from switching to the normal refresh address CXADD midway through the plurality of cycles within a single refresh instruction signal.

According to the fourth embodiment, as described above, a plurality of unused word lines are refreshed consecutively in short cycles, and therefore the number of refresh instruction signals required to refresh all of the used word lines and unused word lines once can be reduced. By refreshing all of the memory cells using a small number of refresh instruction signals, a memory cell having a poor refresh ability can be passed as a normal bit.

### Fifth Embodiment

Next, a fifth embodiment will be described in detail with reference to the drawings. No differences exist in the overall configurations of the semiconductor device 30 according to the first embodiment and a semiconductor device 30d according to the fifth embodiment, and therefore description corresponding to FIG. 2 has been omitted in relation to the semiconductor device 30a.

In the semiconductor device 30d according to the fifth embodiment, a plurality of dummy word lines are activated simultaneously by a single refresh instruction signal, thereby further reducing the number of refresh instruction signals required to refresh each used word line and unused word line once.

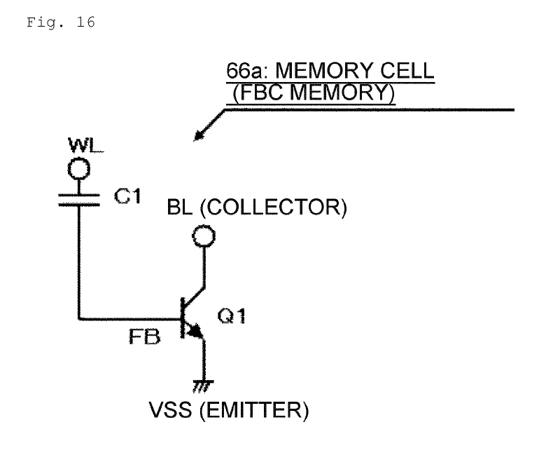

FIG. 15 is a circuit layout diagram showing the periphery of a memory cell region according to the fifth embodiment. In FIG. 15, identical constituent elements to rig. 4 have been allocated. identical reference symbols, and description thereof has been omitted. FIG. 15 differs from FIG. 4 in that the plurality of dummy word. lines (in FIG. 15, the dummy word lines DmyWL1 and DmyWL2) included in the cell region 61 are gathered together in a single node WLD. Since the plurality of dummy word lines are gathered together in the single node WLD, the potential of the node WLD is shifted once from the word line standby voltage VWLS to the word line, overshoot voltage VWLH, and the returned to the word line standby voltage VWLS. By implementing this control, the plurality of dummy word lines are refreshed once. Note that the number of dummy word lines that are activated simultaneously is set. appropriately in consideration of load capacities of the dummy word lines and a drivability of a circuit serving as an internal, power supply that generates the word. line overshoot, voltage VWLH and the word line standby voltage VWLS.

With the semiconductor device 30d according to the fifth embodiment, as described above, a plurality of dummy word lines are refreshed together, and therefore the number of generated refresh instruction signals is reduced.

### Sixth Embodiment

In a semiconductor device 30e according to a sixth embodiment, the end memory cells and the bit lines BL are electrically disconnected. More specifically, the bit line contact 11 is preferably not formed for the end dummy word lines.

When a continuous pattern of memory cells or the like is formed in a normal semiconductor miniaturization process, a shape, dimensions, and so on of a mask pattern are determined by performing a lithography simulation of photolithography to ensure that a regular, continuous pattern is formed with a desired finish. However, in locations near the ends of The cell region, where the continuous pattern is interrupted, an identical mask pattern to that of the continuous memory cells on the inner side is not. formed. in a desired shape. Therefore, the mask pattern of The memory cells in locations close to the ends of the cell region is corrected by performing a further lithography simulation of photolithography, a stress estimation, and so on with the aim of making the actual finished shape identical to the shapes of the memory cells on the inner side. However, even when these corrections are applied, it is substantially impossible to make the shapes of the memory cells in locations close to the ends of the cell region completely identical to the shapes of the continuous memory cells on The inner side. The ends of the cell region are particularly likely to deform when a. complicated shape is employed, and the diffusion layer 4, the electrode 15, and so on shown in FIG. 6 serve as representative examples of such complicated shapes.

When a comparatively simple shape such as the bit line contact 11 is formed, on the other hand, the ends of the cell region can easily be formed in a similar shape to the inner side of the cell region. Further, since the shape deforms steadily more greatly toward the ends of the cell region, the electric characteristics of the memory cells differ steadily more greatly from the memory cell s on the :inner side toward the ends of the cell region.

In the semiconductor device 30e according to the sixth embodiment, the bit line, contact 11 is not formed for the dummy word lines wired to the ends where the continuity of the memory cells is interrupted. More specifically, as shown in FIGS. 4 to 6, the bit line contact 11 is not disposed in the end memory cell 66-2, and therefore the end memory cell is electrically disconnected from the bit line BL. FIG. 5 shows a bit line contact mask pattern 11-2 as an example of this mask pattern. The bit line contact mask pattern 11-2 is disposed in the memory cell 66, but is not disposed in the end memory cell 66-2.

Note that in the examples shown in FIGS. 4 and 15, two dummy word lines are disposed, and the end memory cell 66-2, in which the bit line contact 11 is not disposed, is connected to the dummy word line DmyWL2 located furthest toward the end of the cell region, of the two dummy word lines. However, the number of dummy word lines and the number of word lines connected to the end memory cell 66-2 in which the bit line contact 11 is not disposed do not have to be limited to this example, and appropriate numbers May be set in accordance with the shapes and electric characteristics of the memory cells located close to the ends of the cell region.

Further, in the examples shown in FIGS. 4 and 15, the dummy word line to which the end memory cell 66-2 is connected is also operated during the refresh operation, but. as long as the dummy word line can be electrically disconnected from the bit line reliably, the dummy word line does not necessarily have to be operated.

### Re: Applicable Memory

A method of setting the FB node of a memory cell, connected to an unused word line at a predetermined voltage periodically by operating the unused word line during a refresh operation and a method of electrically disconnecting the memory cell from a bit line were described above in relation to The memory cell shown in FIG. 3. However, the method of writing a data Low to a memory cell disclosed in the present application is not limited to the memory cell shown in FIG. 3, and may be applied to any memory cell that stores a charge in a floating body node.

FIG. 16 is a view showing an example of a circuit diagram of a memory cell of an FBC memory. FIG. 16 differs from FIG. 3A, which is a circuit diagram of the memory cell according to the first embodiment, in that the collector of the bipolar transistor Q1 is connected to the bit line BL, the emitter is grounded to the voltage VSS, and the base serves as the FB node, which is connected to one end of she capacitor C1. The other end of the capacitor C1 is connected to the word line WL, similarly to the memory cell according to the first embodiment.

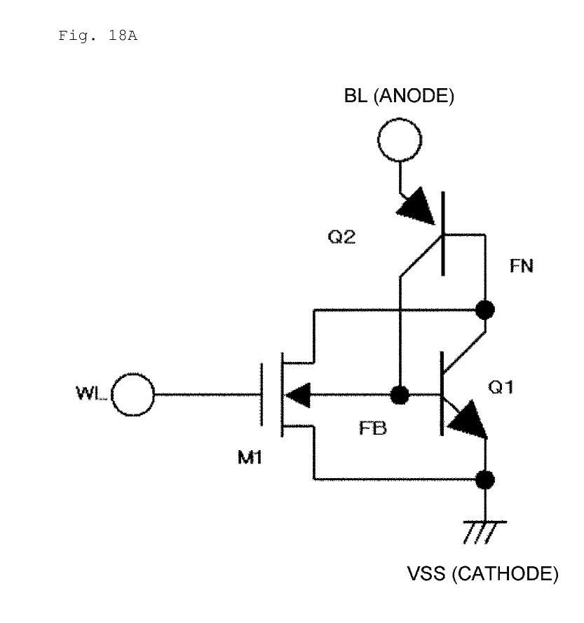

Further, FIG. 17 is a sectional view of the memory cell shown in FIG. 16. FIG. 17 differs from the sectional view of the memory cell (the thyristor memory) according to the first embodiment, shown in FIG. 6, in that the P-type anode (the P-type diffusion layer) 9 is not provided between the N-type diffusion layer 8 and the bit line contact (the P-type polysilicon) 11, and instead, the N-type diffusion layer 8 is directly connected to the bit line contact (the P-type polysilicon) 11. Note that the example of a memory cell shown in FIGS. 16 and 17 was undisclosed at least at The time of filing of the present application.

As regards the peripheral circuits and operation timings of the memory cell, the memory cell can be operated at identical operation timings using a substantially identical circuit configuration to that of the semiconductor device 30 according to the first embodiment. In other words, the first to sixth embodiments can also be applied to the memory cell shown in FIGS. 16 and 17.

Note that the disclosures of the cited patent documents and so on are incorporated herein by reference. The embodiments and examples can be modified and adjusted within the scope of the entire disclosure of the present invention (including the claims) and on the basis of the underlying technical spirit thereof. Furthermore, the various disclosed elements (including respective elements of the claims, respective elements of the embodiments, respective elements of the drawings, and so on) within the scope of the claims of the present invention may be combined and selected variously. In other words, the present invention naturally includes various amendments and modifications that could be implemented by persons skilled in the art in accordance with the entire disclosure, including the claims, and the technical spirit. of the present invention. As regards numerical ranges described in the specification in particular, numerical values and smaller ranges included within these ranges are to be interpreted as specific description, even in the absence of description to the contrary.

### EXPLANATION OF REFERENCE NUMERALS

1 P-type semiconductor substrate

2 N-type cathode

3 P-body (FB)

4 diffusion layer

5 embedded metal

6 STI

7 recess

8 N-type diffusion layer

9 P-type anode (P-type diffusion layer)

10 interlayer film (oxidation film)

11 bit line contact (P-type polysilicon)

11-2 bit line contact mask pattern

12 bit line (metal layer)

13 side wall (nitride film)

14 capacitance contact

15 electrode

16 capacitance film

17 word line

30, 30a to 30e semiconductor device

31 address input circuit

32 address latch circuit

33 command input circuit

34 command decoding circuit

35 clock input circuit

36 timing generator

37 DLL circuit

38 mode register

39 column decoder

40, 40a refresh control circuit

41 memory cell array

42 row decoder

43 SA control circuit

44 FIFO circuit

45 data input/output circuit

46 internal power supply generation circuit

60 region shown in enlarged view in FIG. 4

61-1 to 61-5 cell region

62-1, 62-2 SWD region

63-1, 63-2 sense amplifier region (SA region)

66, 66a memory cell

66-2 end memory cell

69 region shown in enlarged view in FIG. 5

70 memory cell region

71, 71a redundancy determination circuit

72 refresh address counter

73, 73a redundant fuse decoder

74 WL timing control circuit

75 refresh timing circuit

1. A semiconductor device comprising:
a word line;
a bit line;
a power supply node;
a plurality of memory elements including at least first and second regions that form a PN junction between the bit line and the power supply node, and a third region that forms a PN junction with the second region; and
a control circuit which, during a refresh operation, activates both a used word line that is accessed during reading and writing operations and an unused word line that is not accessed during the reading and writing operations, and sets a potential of the second region of each of the used word line and the unused word line at a predetermined voltage.

2. The semiconductor device according to claim 1, wherein the unused word line is a replaced word line replaced in a redundancy replacement process, and/or an unused redundant word line not used in the replacement process, and/or a dummy word line.

3. The semiconductor device according to claim 2, further comprising a refresh address counter that counts not only an address value of the used word line but also an address value of the unused word line.

4. The semiconductor device according to claim 3, further comprising a redundancy determination circuit that performs a logical operation on a redundancy determination output and a refresh address serving as an output of the refresh address counter in order to determine whether the refresh address is an address of the used word line or an address of the unused word line, and outputs the determination output.

5. The semiconductor device according to claim 4, wherein the plurality of memory elements are defined as memory elements that hold first and second data respectively when the respective second regions thereof are at a first level and a second level that is higher than the first level, and
when, based on the determination output, the refresh address is the address of the unused word line, a potential of the second region of the memory element connected to the unused word line is set at the first level.

6. The semiconductor device according to claim 4, wherein the plurality of memory elements are defined as memory elements that hold first and second data respectively when the respective second regions thereof are at a first level and a second level that is higher than the first level, and
when, based on the determination output, the refresh address is the address of the unused word line, a potential of the second region of the memory element connected to the unused word line is set at a lower potential than the first level.

7. The semiconductor device according to claim 5, wherein when, based on the determination output, the refresh address is the address of the unused word line, an operation of a sense amplifier is stopped, and the word line is operated.

8. The semiconductor device according to claim 7, wherein when, based on the determination output, the refresh address is the address of the unused word line, a voltage of the word line is set at a third word line voltage, which is higher than a second word line voltage that is applied to the word line when data are written to the memory element, from a first word line voltage, whereupon the voltage of the word line is set at the second word line voltage and then at the first word line voltage.

9. The semiconductor device according to claim 7, wherein when, based on the determination output, the refresh address is the address of the unused word line, a voltage of the word line is set at a third word line voltage, which is higher than a second word line voltage that is applied to the word line when data are written to the memory element, from a first word line voltage, and then set at the first word line voltage without being held at the second word line voltage.

10. The semiconductor device according to claim 4, comprising a function for determining whether the refresh address is the address of the used word line or the address of the unused word line by performing a logical operation on the redundancy determination output and the refresh address, outputting the determination output, and counting the address of the unused word line consecutively during an address count by the refresh address counter.

11. The semiconductor device according to claim 10, wherein, in response to a single refresh instruction signal, an operation for performing a plurality of address counts and an operation for setting the potentials of the second regions of the memory elements connected to a plurality of the unused word lines at the predetermined level are respectively performed continuously.

12. The semiconductor device according to claim 11, wherein the number of address counts performed in response to a single refresh instruction signal is set at a factor of the number of addresses of the unused word lines.

13. The semiconductor device according to claim 1, wherein an operation is performed to connect all or a plurality of the dummy word lines in the semiconductor device and drive the dummy word lines such that the potentials of the respective second regions of the memory elements connected to all or the plurality of the driven dummy word lines are set simultaneously at the predetermined level.

14. The semiconductor device according to claim 1, wherein the memory elements connected to one or a plurality of dummy word lines located at ends of respective memory regions are electrically disconnected from the bit line.

15. The semiconductor device according to claim 14, wherein the memory elements connected to the dummy word lines are disconnected from the bit line by not forming a bit line contact in the memory elements.

16. The semiconductor device according to claim 1, wherein the memory element is a thyristor further having a fourth region that forms a PN junction with the third region and is removed from the second region, and the bit line is electrically connected to the fourth region.

17. The semiconductor device according to claim 1, wherein the memory element is a bipolar transistor, and the bit line is electrically connected to the third region.
